(19) United States
(12) Patent Application Publication
(10) Pub. No.: US 2026/0181957 A1
(43) Pub. Date: Jun. 25, 2026

(54) THIN FILM TRANSISTOR HAVING BARRIER LAYER AND DISPLAY DEVICE COMPRISING THE SAME

(71) Applicant: LG Display Co., Ltd., Seoul (KR)

(72) Inventors: DaeHwan KIM, Paju-si (KR); Jaeyoon PARK, Paju-si (KR); Dongyeon KANG, Paju-si (KR)

(73) Assignee: LG Display Co., Ltd., Seoul (KR)

(21) Appl. No.: 19/394,715

(22) Filed: Nov. 19, 2025

(30) Foreign Application Priority Data
Dec. 24, 2024 (KR) 10-2024-0195881

(51) Int. Cl. H10D 30/67

(52) U.S. Cl. CPC H10D 30/6736; H10D 30/6757

(57) ABSTRACT

The present disclosure relates to a thin film transistor and a display device including the same and manufacturing method thereof. A thin film transistor is provided, which includes an active layer, a gate insulating layer on the active layer, a gate electrode on the gate insulating layer, and a first barrier layer on the gate insulating layer, wherein the gate electrode and the first barrier layer are arranged to be spaced apart from each other, a portion of the active layer overlaps the gate electrode to form a channel portion in the active layer, the first barrier layer overlaps another portion of the active layer.

### CROSS-REFERENCE TO RELATED APPLICATIONS

This application claims the priority and benefit of the Korean Patent Application No. 10-2024-0195881 filed on Dec. 24, 2024, which is hereby incorporated by reference in its entirety for all purpose as if fully set forth herein.

### TECHNICAL FIELD

The present disclosure relates to a thin film transistor and a display device comprising the same, and more particularly, for example, without limitation, to a technique for forming a non-conductorized region in at least a portion of an active layer by using a barrier layer during a doping process.

### DISCUSSION OF THE RELATED ART

Since a thin film transistor can be manufactured on a glass substrate or a plastic substrate, the thin film transistor is widely used as a switching element or a driving element of a display device such as a liquid crystal display device or an organic light emitting display device.

The thin film transistor may be categorized into an amorphous silicon thin film transistor in which amorphous silicon is used as an active layer, a polycrystalline silicon thin film transistor in which polycrystalline silicon is used as an active layer, and an oxide semiconductor thin film transistor in which oxide semiconductor is used as an active layer, depending on a material constituting the active layer.

An oxide semiconductor thin film transistor (TFT), which has high mobility and has a large resistance change in accordance with an oxygen content, has an advantage in that desired properties may be easily obtained. Since an oxide constituting an active layer may be grown at a relatively low temperature during a process of manufacturing the oxide semiconductor thin film transistor, the manufacturing cost of the oxide semiconductor thin film transistor is reduced. Furthermore, in view of the properties of the oxide, since an oxide semiconductor is transparent, it is favorable to embody a transparent display.

The description provided in the discussion of the related art section should not be assumed to be prior art merely because it is mentioned in or associated with that section. The discussion of the related art section may include information that describes one or more aspects of the subject technology, and the description in this section does not limit the disclosure.

### SUMMARY

Generally, a high-resolution display device includes a large number of thin film transistors. In order to arrange a large number of thin film transistors in a certain area, a size of the thin film transistor should be reduced. However, it is newly recognized by the inventors of the present disclosure that, when the size of the thin film transistor is reduced, a channel length also becomes shorter, which may deteriorate driving stability of the thin film transistor or cause a characteristic deviation between the thin film transistors, whereby display quality of the display device may be deteriorated.

In order for the thin film transistor to operate stably, a channel needs to have an effective channel length greater than a specific value. In case of an oxide semiconductor thin film transistor having a coplanar structure, it is important to control a conductorized region to make sure of the channel length.

In the oxide semiconductor thin film transistor, a phenomenon in which a conductorized region is permeated into the channel after a doping process may occur. In an oxide semiconductor thin film transistor having a short channel length, the effective channel length of the thin film transistors becomes very short due to the permeated conductorized region, which may make it difficult to control a carrier concentration of the effective channel.

In this way, the permeated conductorized region is an important factor that deteriorates electrical characteristics of the oxide semiconductor thin film transistor having a short channel length. Therefore, in order to control the electrical characteristics of the oxide semiconductor thin film transistor, it is necessary to control a depth of the permeated conductorized region, thereby making sure of a constant effective channel length.

Accordingly, embodiments of the present disclosure are directed to a thin film transistor having a barrier layer and a display device comprising the same that substantially obviates one or more of the problems due to limitations and disadvantages of the related art.

An aspect of the present disclosure is to provide a technique for forming a non-conductorized region in at least a portion of an active layer by using a barrier layer during a doping process.

Another aspect of the present disclosure is to provide a thin film transistor capable of having a constant effective channel length by controlling a permeation depth of a conductorized region by using a barrier layer.

Another aspect of the present disclosure is to provide a display device comprising the thin film transistor.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a thin film transistor comprises an active layer, a gate insulating layer on the active layer, a gate electrode on the gate insulating layer, and a first barrier layer on the gate insulating layer, wherein the gate electrode and the first barrier layer are arranged to be spaced apart from each other, a portion of the active layer overlaps the gate electrode to form a channel portion in the active layer, the first barrier layer overlaps another portion of the active layer.

The first barrier layer overlaps another portion of the active layer to form a first non-doping portion in the active layer, the active layer includes a channel portion overlapping the gate electrode and having a first side and a second side, and a first connection portion that is in contact with the first side of the channel portion, the first connection portion includes a first doping portion and a first non-doping portion, and the first non-doping portion overlaps the first barrier layer but does not overlap the gate electrode.

The first non-doping portion may have a carrier concentration higher than that of the channel portion.

The thin film transistor according to one exemplary embodiment of the present disclosure may further comprise a source electrode that is in contact with the active layer, wherein the source electrode may be in contact with the first doping portion of the first connection portion.

The source electrode may be in contact with the first barrier layer.

The first barrier layer may include the same material as that of the gate electrode, and may not be electrically connected to the gate electrode.

The first barrier layer may have the same thickness as that of the gate electrode.

According to another exemplary embodiment of the present disclosure, the thin film transistor may further comprise a second barrier layer on the gate insulating layer, wherein the gate electrode and the second barrier layer are arranged to be spaced apart from each other, the second barrier layer overlaps the active layer but does not overlap the first connection portion, and the second barrier layer is arranged in a drain region.

The active layer further includes a second connection portion that is in contact with the second side of the channel portion, the second connection portion includes a second doping portion and a second non-doping portion, and the second non-doping portion overlaps the second barrier layer but does not overlap the gate electrode and the first barrier layer.

The second non-doping portion may have a carrier concentration higher than that of the channel portion.

The thin film transistor according to another exemplary embodiment of the present disclosure may further comprise a source electrode that is in contact with the active layer, wherein the source electrode may be in contact with the first doping portion of the first connection portion.

The source electrode may be in contact with the first barrier layer and the second barrier layer.

Each of the first barrier layer and the second barrier layer may include the same material as that of the gate electrode, and may not be electrically connected to the gate electrode.

Each of the first barrier layer and the second barrier layer may have the same thickness as that of the gate electrode.

Each of the first barrier layer and the second barrier layer may have a spaced distance from the gate electrode in the range of 1.5 μm to 3.0 μm.

Each of the first barrier layer and the second barrier layer may have a first line segment and a second line segment, a length of each of the first line segment and the second line segment of the first barrier layer may range from 1.5 μm to 2.5 μm, and a length of each of the first line segment and the second line segment of the second barrier layer may range from 1.5 μm to 2.5 μm.

In this case, the first line segment of the first barrier layer is a side facing the gate electrode among line segments defining a surface in which the first barrier layer and the gate insulating layer are in contact with each other, and the second line segment of the first barrier layer is a side intersecting the first line segment of the first barrier layer, and the first line segment of the second barrier layer is a side facing the gate electrode among line segments defining a surface in which the second barrier layer and the gate insulating layer are in contact with each other, and the second line segment of the second barrier layer is a side intersecting the first line segment of the second barrier layer.

According to the thin film transistor of another exemplary embodiment of the present disclosure, the first barrier layer is arranged in a source region, and the first barrier layer further includes at least one first sub-barrier layer, the gate electrode and the first sub-barrier layer are arranged to be spaced apart from each other, the first barrier layer and the first sub-barrier layer are arranged to be spaced apart from each other, the first sub-barrier layer is arranged in the source region, and a portion of the active layer overlaps the first sub-barrier layer.

According to the thin film transistor of another exemplary embodiment of the present disclosure, the second barrier layer further includes at least one second sub-barrier layer, the gate electrode and the second sub-barrier layer are arranged to be spaced apart from each other, the second barrier layer and the second sub-barrier layer are arranged to be spaced apart from each other, the second sub-barrier layer is arranged in a drain region, and a portion of the active layer overlaps the second sub-barrier layer.

A spaced distance between the first barrier layer and the gate electrode may be the same as a spaced distance between the first sub-barrier layer and the gate electrode, and a spaced distance between the second barrier layer and the gate electrode may be the same as a spaced distance between the second sub-barrier layer and the gate electrode.

The spaced distance between the first barrier layer and the gate electrode may be different from the spaced distance between the first sub-barrier layer and the gate electrode, and the spaced distance between the second barrier layer and the gate electrode may be different from the spaced distance between the second sub-barrier layer and the gate electrode.

Each of the first barrier layer, the second barrier layer, the first sub-barrier layer, and the second sub-barrier layer may have a first line segment and a second line segment, a length of at least one of the first line segment or the second line segment of the first barrier layer may be different from a length of at least one of the first line segment or the second line segment of the first sub-barrier layer, and a length of at least one of the first line segment or the second line segment of the second barrier layer may be different from a length of at least one of the first line segment or the second line segment of the second sub-barrier layer.

In this case, the first line segment of the first barrier layer is a side facing the gate electrode among line segments defining a surface in which the first barrier layer and the gate insulating layer are in contact with each other, and the second line segment of the first barrier layer is a side intersecting the first line segment of the first barrier layer, the first line segment of the first sub-barrier layer is a side facing the gate electrode among line segments defining a surface in which the first sub-barrier layer and the gate insulating layer are in contact with each other, and the second line segment of the first sub-barrier layer is a side intersecting the first line segment of the first sub-barrier layer, the first line segment of the second barrier layer is a side facing the gate electrode among line segments defining a surface in which the second barrier layer and the gate insulating layer are in contact with each other, and the second line segment of the second barrier layer is a side intersecting the first line segment of the second barrier layer, and the first line segment of the second sub-barrier layer is a side facing the gate electrode among line segments defining a surface in which the second sub-barrier layer and the gate insulating layer are in contact with each other, and the second line segment of the second sub-barrier layer is a side intersecting the first line segment of the second sub-barrier layer.

In another aspect, a display device comprising the above thin film transistor is provided.

Purposes according to the present disclosure are not limited to the above-mentioned purpose. Other purposes and advantages according to the present disclosure that are not mentioned may be understood based on following descriptions, and may be more clearly understood based on embodiments according to the present disclosure. Further, it will be easily understood that the purposes and advantages according to the present disclosure may be realized using means shown in the claims or combinations thereof.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles. In the drawings:

FIG. 1 is a plan view illustrating a thin film transistor according to one exemplary embodiment of the present disclosure;

FIG. 2 is a cross-sectional view taken along line I-I′ of FIG. 1;

FIG. 3 is a cross-sectional view taken along line II-II′ of FIG. 1;

FIG. 4 is a schematic cross-sectional view illustrating a thin film transistor according to another exemplary embodiment of the present disclosure;

FIG. 5A is a schematic view illustrating conductorization of a thin film transistor according to a comparative example, and FIG. 5B is a schematic view illustrating a conductorization permeation depth ΔL of a thin film transistor according to a comparative example;

FIG. 6A is a schematic view illustrating conductorization of a thin film transistor according to one exemplary embodiment of the present disclosure, and FIG. 6B is a schematic view illustrating a conductorization permeation depth ΔL of a thin film transistor according to one exemplary embodiment of the present disclosure;

FIG. 7 is a graph for position-specific carrier concentration at a CL (Center Line) of an active layer of a thin film transistor according to one exemplary embodiment of the present disclosure and a thin film transistor according to a comparative example;

FIG. 8 is a graph for position-specific sheet resistance distribution at a CL (Center Line) of an active layer of a thin film transistor according to one exemplary embodiment of the present disclosure;

FIG. 9 is a schematic plan view illustrating a relation between a barrier layer of a thin film transistor and a conductorization permeation depth ΔL according to one exemplary embodiment of the present disclosure;

FIG. 10A is a graph for position-specific carrier concentration at a CL (Center Line) of an active layer according to each area of a barrier layer of a thin film transistor according to one exemplary embodiment of the present disclosure, and FIG. 10B is a current graph for each area of a barrier layer;

FIG. 11A is a graph for position-specific carrier concentration at a CL (Center Line) of an active layer according to each spaced distance between a barrier layer and a gate electrode of a thin film transistor according to one exemplary embodiment of the present disclosure, and FIG. 11B is a current graph for each spaced distance between the barrier layer and the gate electrode;

FIGS. 12 to 16 are schematic plan views according to a shape and arrangement of a barrier layer of a thin film transistor according to further embodiments of the present disclosure;

FIG. 17 is a schematic cross-sectional view illustrating a thin film transistor according to further embodiments of the present disclosure;

FIGS. 18A to 18F are schematic cross-sectional views illustrating a method of manufacturing a thin film transistor according to further embodiments of the present disclosure;

FIG. 19 is a schematic view illustrating a display device according to further embodiment of the present disclosure; and

FIG. 20 is a circuit view for one pixel of FIG. 19.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to embodiments of the present disclosure, examples of which may be illustrated in the accompanying drawings. The progression of processing steps and/or operations described is an example; however, the sequence of steps and/or operations is not limited to that set forth herein and may be changed as is known in the art, with the exception of steps and/or operations necessarily occurring in a particular order. Names of the respective elements used in the following explanations may be selected only for convenience of writing the specification and may be thus different from those used in actual products.

Advantages and features of the present disclosure and implementation methods thereof will be clarified through following exemplary embodiments described with reference to the accompanying drawings. The present disclosure may, however, be embodied in different forms and should not be construed as limited to the exemplary embodiments set forth herein. Rather, these embodiments are provided so that this disclosure will be sufficiently thorough and complete and will fully convey the scope of the present disclosure to those skilled in the art. Further, the present disclosure is only defined by scopes of claims.

A shape, a size, a ratio, an angle and a number, and the like disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the aspects of the present disclosure, the detailed description will be omitted.

In a case where ‘comprise’, ‘have’, ‘include’, “constitute,” “make up of,” “formed of,” and the like described in the present disclosure are used, another portion may be added unless ‘only˜’ is used. The terms of a singular form may include plural forms unless referred to the contrary.

In construing an element, the element is construed as including an error band although there is no explicit description. Any implementation described herein as an “example” is not necessarily to be construed as preferred or advantageous over other implementations.

In describing a position relationship, for example, when the position relationship is described as “on˜”, “over˜”, ‘upon˜’, ‘above˜’, ‘below˜’, “beneath˜” and ‘next to˜’, one or more portions may be arranged between two other portions unless ‘just’ or ‘direct’ is used, for example, one or more other parts may be disposed located between the two parts. For example, where an element or layer is disposed “on” another element or layer, a third layer or element may be interposed therebetween.

Spatially relative terms such as “below”, “beneath”, “lower”, “above”, and “upper” may be used herein to easily describe a relationship of one element or elements to another element or elements as illustrated in the drawings. It will be understood that these terms are intended to encompass different orientations of the device in addition to the orientation depicted in the drawings. For example, if the device illustrated in the figure is reversed, the device described to be arranged “below”, or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” “A” “B” “(A)” or “(B)” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

In the addition of reference numerals to the components of each drawing describing embodiments of the present disclosure, the same components can have the same sign as can be displayed on the other drawings.

In the embodiments of the present disclosure, a source electrode and a drain electrode are distinguished for convenience of description, and the source electrode and the drain electrode may be interchanged. The source electrode may be the drain electrode and vice versa. In addition, the source electrode of any one exemplary embodiment may be a drain electrode in another embodiment, and the drain electrode of any one exemplary embodiment may be a source electrode in another embodiment.

In some embodiments of the present disclosure, for convenience of description, a source connector is distinguished from a source electrode, and a drain connector is distinguished from a drain electrode, but embodiments of the present disclosure are not limited thereto. The source connector may be the source electrode, and the drain connector may be the drain electrode. In addition, the source connector may be the drain electrode, and the drain connector may be the source electrode.

In the exemplary embodiments of the present disclosure, a region with which a source electrode is in contact may be referred to as a source region, a region with which a drain electrode is in contact may be referred to as a drain region, and a region arranged between the source region and the drain region may be referred to as a channel region.

Hereinafter, example embodiments of the present disclosure will be described in detail with reference to the accompanying drawings. The scales of the components shown in the drawings have different scales from the actual ones for convenience of explanation, and thus are not limited to the scales shown in the drawings.

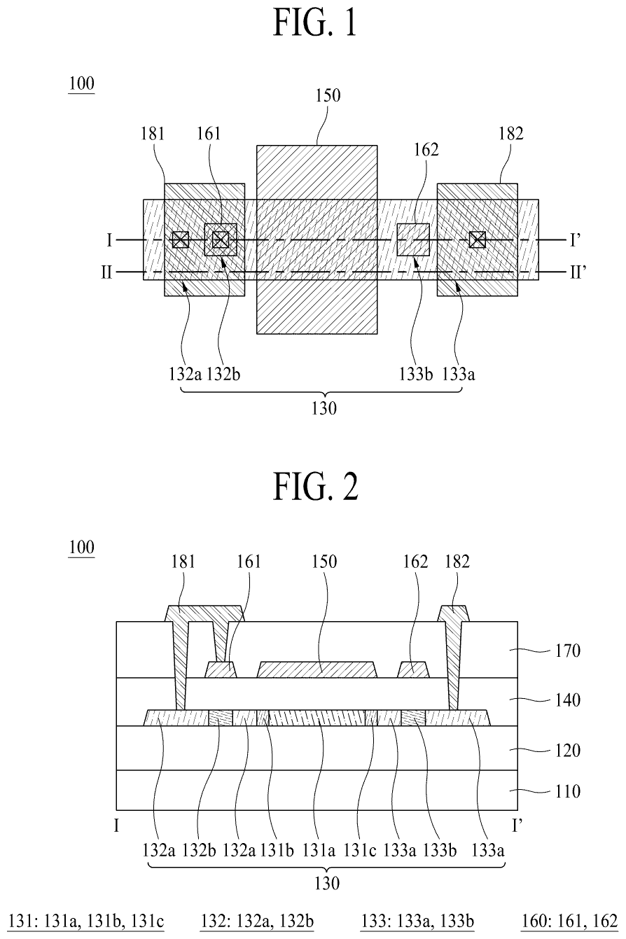

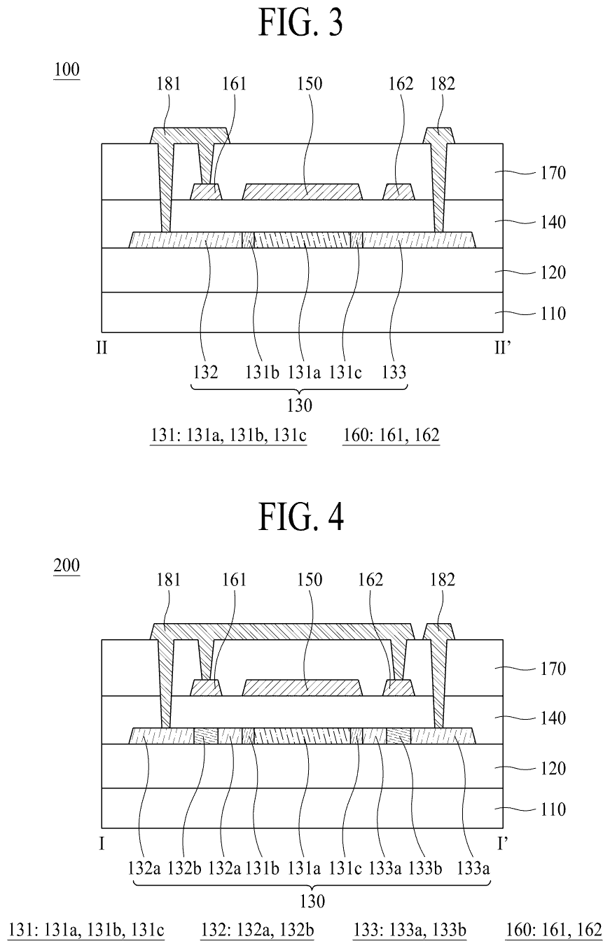

FIG. 1 is a plan view illustrating a thin film transistor 100 according to one exemplary embodiment of the present disclosure. FIG. 2a is a cross-sectional view taken along line I-I′ of FIG. 1, and FIG. 3 is a cross-sectional view taken along line II-II′ of FIG. 1.

Referring to FIGS. 1 to 3, the thin film transistor 100 according to one exemplary embodiment of the present disclosure includes an active layer 130, a gate insulating layer 140 on the active layer 130, a gate electrode 150 on the gate insulating layer 140, and a barrier layer 160 on the gate insulating layer 140. The gate electrode 150 is spaced apart from the active layer 130. A portion of the active layer 130 overlaps the gate electrode 150, and another portion of the active layer 130 overlaps the barrier layer 160.

For example, the gate electrode 150 and the barrier layer 160 are spaced apart from the active layer 130. The gate insulating layer 140 may be disposed between the gate electrode 150 and the active layer 130, and between the barrier layer 160 and the active layer 130.

Referring to FIGS. 2 and 3, the thin film transistor 100 may be arranged on the substrate 110.

The substrate 110 supports components of the thin film transistor 100. As long as it supports the thin film transistor 100, it may be referred to as the substrate 110 without limitation.

A glass substrate or a polymer resin substrate may be used as the substrate 110. A plastic substrate may be used as the polymer resin substrate. The plastic substrate may include at least one of polyimide (PI), polycarbonate (PC), polyethylene (PE), polyester, polyethylene terephthalate (PET), or polystyrene (PS), which has flexible characteristics. When plastic is used as the substrate 110, heat-resistant plastic capable of withstanding high temperatures may be used considering that a high-temperature deposition process is performed on the substrate 110.

According to one exemplary embodiment of the present disclosure, a buffer layer 120 may be arranged on the substrate 110, and the active layer 130 may be arranged on the buffer layer 120.

The buffer layer 120 is arranged on the substrate 110, and may be formed of an inorganic material or an organic material. For example, the buffer layer 120 may include an insulating oxide such as silicon oxide (SiOₓ) and aluminum oxide (Al₂O₃).

The buffer layer 120 protects the active layer 130 by blocking impurities, such as moisture and oxygen, which are introduced from the substrate 110, serves to planarize an upper portion of the substrate 110, and may be formed as a single layer or a plurality of layers. If necessary, the buffer layer 120 may be omitted.

The active layer 130 is arranged on the buffer layer 120 and includes an oxide semiconductor material. According to one exemplary embodiment of the present disclosure, the active layer 130 may be, for example, an oxide semiconductor layer made of an oxide semiconductor material.

The active layer 130 may include at least one of, for example, IGZO(InGaZnO)-based, IGO(InGaO)-based, IGZTO (InGaZnSnO)-based, GZTO(GaZnSnO)-based, GZO(GaZnO)-based, GO(GaO)-based, TO(SnO)-based, ITO (InSnO)-based, ITZO(InSnZnO)-based, IZO(InZnO)-based, ZO(ZnO)-based, IO(InO)-based, InO(InO)-based, ZnO-based or FIZO(FeInZnO)-based oxide semiconductor material.

The active layer 130 may have a single layer structure, or a multilayer structure including two or more oxide semiconductor layers.

According to one exemplary embodiment of the present disclosure, the active layer 130 includes a channel portion 131, a first connection portion 132, and a second connection portion 133.

The channel portion 131 may have a first side and a second side opposite to the first side, and the first side of the channel portion 131 may contact the first connection portion 132, and the second side of the channel portion 131 may contact the second connection portion 133.

The channel portion 131 may be arranged between the first connection portion 132 and the second connection portion 133. For example, the active layer 130 may cover a portion of the buffer layer 120, and the gate insulating layer 140 may cover the remaining portion of the buffer layer 120.

The channel portion 131 overlaps the gate electrode 150. The channel portion 131 has semiconductor characteristics. The channel portion 131 may have electrical characteristics such as a conductor or electrical characteristics such as a non-conductor depending on a voltage applied to the gate electrode 150.

Referring to FIGS. 2 and 3, the channel portion 131 includes an effective channel portion 131a, a first diffusion region 131b, and a second diffusion region 131c. The first side of the effective channel portion 131a may contact the first diffusion region 131b, and the second side of the effective channel portion 131a may contact the second diffusion region 131c.

The first diffusion region 131b refers to a conductorized region formed by diffusion of a carrier as much as a conductorization permeation depth ΔL from the first connection portion 132 to a center direction of the channel portion 131. The second diffusion region 131c refers to a conductorized region formed by diffusion of a carrier as much as a conductorization permeation depth ΔL from the second connection portion 133 to the center direction of the channel portion 131.

The first connection portion 132 is in contact with the first side of the channel portion 131. In more detail, the first connection portion 132 is in contact with the first diffusion region 131b formed on the first side of the channel portion 131.

Referring to FIGS. 1 to 3, the first connection portion 132 may include a first doping portion 132a in contact with the first side of the channel portion 131 and a first non-doping portion 132b formed in an island shape of four surfaces surrounded by the first doping portion 132a. The first doping portion 132a is in contact with the first diffusion region 131b formed on the first side of the channel portion 131. For example, first doping portion 132a and the first non-doping portion 132b do not overlap the gate electrode 150.

The first doping portion 132a does not overlap the gate electrode 150 and a first barrier layer 161. When viewed in a plan view, the first doping portion 132a may be in contact with the first diffusion region 131b formed on the first side of the channel portion 131. Details of the first barrier layer 161 will be described later.

The first non-doping portion 132b does not overlap the gate electrode 150, but overlaps the first barrier layer 161. When viewed in a plan view, the first non-doping portion 132b may be arranged to be spaced apart from the first diffusion region 131b in a shaped surrounded by the first doping portion 132a.

The second connection portion 133 is in contact with the second side of the channel portion 131. In more detail, the second connection portion 133 is in contact with the second diffusion region 131c formed on the second side of the channel portion 131.

Referring to FIGS. 1 to 3, the second connection portion 133 may include a second doping portion 133a that is in contact with the second side of the channel portion 131, and a second non-doping portion 133b formed in an island shape of four surfaces surrounded by the second doping portion 133a. In more detail, the second doping portion 133a is in contact with the second diffusion region 131c formed on the second side of the channel portion 131. For example, the second doping portion 133a and the second non-doping portion 133b do not overlap the gate electrode 150.

The second doping portion 133a does not overlap the gate electrode 150 and the second barrier layer 162. When viewed in a plan view, the second doping portion 133a may be in contact with the second diffusion region 131c formed on the second side of the channel portion 131. Details of the second barrier layer 162 will be described later.

The second non-doping portion 133b does not overlap the gate electrode 150, but overlaps the second barrier layer 162. When viewed in a plan view, the second non-doping portion 133b may be arranged to be spaced apart from the second diffusion region 131c in a shape surrounded by the second doping portion 133a.

According to one exemplary embodiment of the present disclosure, the first doping portion 132a of the first connection portion 132 and the second doping portion 133a of the second connection portion 133 are regions in which an oxide semiconductor material is conductorized. The first doping portion 132a and the second doping portion 133a may be referred to as conductorized portions. The first doping portion 132a and the second doping portion 133a may also be referred to as conductorized regions.

According to one exemplary embodiment of the present disclosure, conductorization refers to improving electrical conductivity of a certain portion of the active layer 130 or providing electrical conductivity to a certain portion of the active layer 130. The conductorized portion of the active layer 130 has excellent electrical conductivity and thus may function as a line portion.

According to one exemplary embodiment of the present disclosure, for example, a region of the entire active layer 130, which does not overlap the gate electrode 150 and the barrier layer 160, may be conductorized. For example, when a doping process for conductorizing the active layer 130 is performed, a region overlapping the gate electrode 150 and the barrier layer 160 may remain in a non-conductorized state because doping is not performed, and a region not overlapping the gate electrode 150 and the barrier layer 160 may be conductorized when the doping process is performed.

According to one exemplary embodiment of the present disclosure, for example, a region of the entire active layer 130, which does not overlap the gate electrode 150 and the barrier layer 160, may be conductorized, for example, the first doping portion 132a and the second doping portion 133a may be conductorized, and the region overlapping the gate electrode 150 and the barrier layer 160 may remain in the non-conductorized state, for example, the first non-doping portion 132b, the second non-doping portion 133b and the channel portion 131 may remain in the non-conductorized state.

As a result of conductorization, the doping portions 132a and 133a may have electrical characteristics similar to those of a conductor. In more detail, each of the first doping portion 132a and the second doping portion 133a may have electrical characteristics similar to those of a metal.

According to one exemplary embodiment of the present disclosure, the first non-doping portion 132b of the first connection portion 132 is a non-conductorized region in which doping is blocked by the first barrier layer 161 and thus an oxide semiconductor material is not conductorized, and the second non-doping portion 133b of the second connection portion 133 is a non-conductorized region in which doping is blocked by the second barrier layer 162 and thus an oxide semiconductor material is not conductorized. The first and second non-doping portions 132b and 133b may be referred to as non-conductorized portions. The first and second non-doping portions 132b and 133b may also be referred to as non-conductorized regions.

According to one exemplary embodiment of the present disclosure, the first non-doping portion 132b and the second non-doping portion 133b are formed by selective non-conductorization with respect to the active layer 130. For example, the oxide semiconductor material constituting the active layer 130 may be selectively non-conductorized to form the first non-doping portion 132b and the second non-doping portion 133b.

The gate insulating layer 140 is arranged on the active layer 130.

According to one exemplary embodiment of the present disclosure, the gate insulating layer 140 may be arranged to cover the entire upper surface of the active layer 130. For example, the gate insulating layer 140 may be arranged to cover the entire upper surface of the active layer 130 and the portion of the upper surface of the buffer layer 120 exposed by the active layer 130. Referring to FIGS. 2 and 3, the gate insulating layer 140 may be arranged to cover the entire upper surface of the buffer layer 120. When the buffer layer 120 is omitted, the gate insulating layer 140 may be arranged to cover the entire upper surface of the substrate 110.

The gate insulating layer 140 may be made of an insulating material containing hydrogen (H). For example, the material for forming the gate insulating layer 140 may contain hydrogen (H). Therefore, according to one exemplary embodiment of the present disclosure, the gate insulating layer 140 may contain hydrogen (H).

The gate insulating layer 140 may include at least one of, for example, silicon oxide (SiOₓ), silicon nitride (SiNₓ), or aluminum oxide (AlOₓ).

The silicon oxide (SiOₓ) may be formed under a condition including silane (SiH₄) and oxygen (O₂). Therefore, the gate insulating layer 140 including silicon oxide (SiOₓ) may include hydrogen.

The silicon nitride (SiNₓ) may be formed under a condition including silane (SiH₄), ammonia (NH₃) and oxygen (O₂). Therefore, the gate insulating layer 140 including silicon nitride (SiNₓ) may include hydrogen.

The aluminum oxide (AlOₓ) may be formed under a condition including an aluminum compound and a hydroxyl group (OH) or moisture (H₂O). Therefore, the gate insulating layer 140 including aluminum oxide (AlOₓ) may include hydrogen.

However, one exemplary embodiment of the present disclosure is not limited to the above examples, and other known insulating materials may be applied to the gate insulating layer 140.

According to one exemplary embodiment of the present disclosure, the gate electrode 150 is arranged on the gate insulating layer 140. The gate electrode 150 is spaced apart from the active layer 130 to at least partially overlap the active layer 130. The gate electrode 150 overlaps the channel portion 131 of the active layer 130.

The gate electrode 150 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti). The gate electrode 150 may have a multilayer structure including at least two conductive layers having different physical properties.

According to one exemplary embodiment of the present disclosure, the barrier layer 160 is arranged on the gate insulating layer 140. The barrier layer 160 is arranged on the gate insulating layer 140 to be spaced apart from the gate electrode 150. Also, the barrier layer 160 is spaced apart from the active layer 130 to at least partially overlap the active layer 130. For example, the barrier layer 160

The barrier layer 160 may include a first barrier layer 161 and a second barrier layer 162.

The first barrier layer 161 overlaps a portion of the active layer 130. The region where the first barrier layer 161 and the active layer 130 overlap each other may be a region different from the region where the gate electrode 150 and the active layer 130 overlap each other. In detail, the first barrier layer 161 at least partially overlaps the first connection portion 132. In more detail, the first barrier layer 161 overlaps the first non-doping portion 132b of the first connection portion 132. The gate electrode 150 overlaps the channel portion 131. The region where the first barrier layer 161 and the active layer 130 overlap each other and the region where the second barrier layer 162 and the active layer 130 overlap each other may be regions different from the region where the gate electrode 150 and the active layer 130 overlap each other.

The second barrier layer 162 overlaps a portion of the active layer 130. The region where the second barrier layer 162 and the active layer 130 overlap each other may be a region different from the region where the gate electrode 150 and the active layer 130 overlap each other. In detail, the second barrier layer 162 at least partially overlaps the second connection portion. In more detail, the second barrier layer 162 overlaps the second non-doping portion 133b of the second connection portion 133.

According to one exemplary embodiment of the present disclosure, the first barrier layer 161 may prevent or reduce at least a portion of the first connection portion 132 from being conductorized during the doping process, such that the first non-doping portion 132b, which is a non-conductorized region, is formed in at least a portion of the first connection portion 132. Furthermore, the second barrier layer 162 may prevent or reduce at least a portion of the second connection portion 133 from being conductorized during the doping process, such that the second non-doping portion 133b, which is a non-conductorized region, is formed in at least a portion of the second connection portion 133.

For example, the first barrier layer 161 may prevent or reduce the first non-doping portion 132b of the first connection portion 132 from being conductorized during the doping process. The second barrier layer 162 may prevent or reduce the second non-doping portion 133b of the second connection portion 133 from being conductorized during the doping process.

According to one exemplary embodiment of the present disclosure, the first barrier layer 161 may be arranged in the source region, for example, and the second barrier layer 162 may be arranged in the drain region, for example.

According to one exemplary embodiment of the present disclosure, the barrier layer 160 is arranged to be spaced apart from the gate electrode 150.

According to one exemplary embodiment of the present disclosure, the gate electrode 150 and the barrier layer 160 may include the same material. In more detail, the barrier layer 160 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or a molybdenum alloy, chromium (Cr), tantalum (Ta), neodymium (Nd), or titanium (Ti).

According to one exemplary embodiment of the present disclosure, the gate electrode 150 and the barrier layer 160 are not electrically connected to each other. In more detail, the first barrier layer 161 is not electrically connected to the gate electrode 150, and the second barrier layer 162 is not electrically connected to the gate electrode 150. For example, the interlayer insulating layer 170 may be arranged between the first barrier layer 161 and the gate electrode 150, and between the second barrier layer 162 and the gate electrode 150.

According to one exemplary embodiment of the present disclosure, the gate electrode 150 and the barrier layer 160 may have the same thickness, but is not limited thereto.

According to one exemplary embodiment of the present disclosure, the gate electrode 150 and the barrier layer 160 are formed by the same process, respectively, but is not limited thereto. Accordingly, the gate electrode 150 and the barrier layer 160 may include the same material, and may have the same thickness., but is not limited thereto

An interlayer insulating layer 170 may be arranged on the barrier layer 160 and the gate electrode 150. The interlayer insulating layer 170 is an insulating layer made of an insulating material. The interlayer insulating layer 170 may be formed of an organic material, an inorganic material, or a laminate of an organic material layer and an inorganic material layer.

A source electrode 181 and a drain electrode 182 are arranged on the interlayer insulating layer 170. The source electrode 181 and the drain electrode 182 are spaced apart from each other, and are connected to the active layer 130, respectively. Each of the source electrode 181 and the drain electrode 182 may be connected to the active layer 130 through a contact hole passing through the interlayer insulating layer 170. Specifically, each of the source electrode 181 and the drain electrode 182 may be connected to the active layer 130 through a contact hole passing through the interlayer insulating layer 170 and the gate insulating layer 140.

Each of the source electrode 181 and the drain electrode 182 may include at least one of molybdenum (Mo), aluminum (Al), chromium (Cr), gold (Au), titanium (Ti), nickel (Ni), neodymium (Nd), copper (Cu), or their alloy. Each of the source electrode 181 and the drain electrode 182 may be formed of a single layer made of a metal or an alloy of the metal, or may be formed of two or more layers.

The source electrode 181 may be connected to the barrier layer 160. The source electrode 181 may be connected to the barrier layer 160 through a separate contact hole passing through the interlayer insulating layer 170 rather than a contact hole connecting the source electrode 181 with the active layer 130. For example, the contact hole connecting the source electrode 181 and the active layer 130 is different from the contact hole connecting the source electrode 181 and the barrier layer 160.

According to one exemplary embodiment of the present disclosure, the source electrode 181 may be in contact with at least one of the first barrier layer 161 or the second barrier layer 162.

Referring to FIGS. 2 and 3, the source electrode 181 may be in contact with the first barrier layer 161, and is not in contact with second barrier layer 162. The source electrode 181 may be in contact with an upper surface of the first barrier layer 161. Also, the source electrode 181 may be in contact with the first doping portion 132a of the first connection portion 132.

Referring to FIGS. 2 and 3, the drain electrode 182 is not in contact with the barrier layer 160, and the source electrode 181 may be in contact with the barrier layer 160. For example, when the second barrier layer 162 is in contact with the drain electrode 182, parasitic capacitance may increase between the gate electrode 150 and the second barrier layer 162. For this reason, circuit performance of the thin film transistor may be reduced.

Referring to FIG. 4, the source electrode 181 may be in contact with the first barrier layer 161 and the second barrier layer 162. The source electrode 181 may be in contact with the upper surface of the first barrier layer 161 and the upper surface of the second barrier layer 162. Also, the source electrode 181 may be in contact with the first doping portion 132a.

As shown in FIG. 4, when the source electrode 181 is in contact with the first barrier layer 161 and the second barrier layer 162, occurrence of parasitic capacitance between the gate electrode 150 and the barrier layer 160 is minimized, thereby improving driving stability of the thin film transistor.

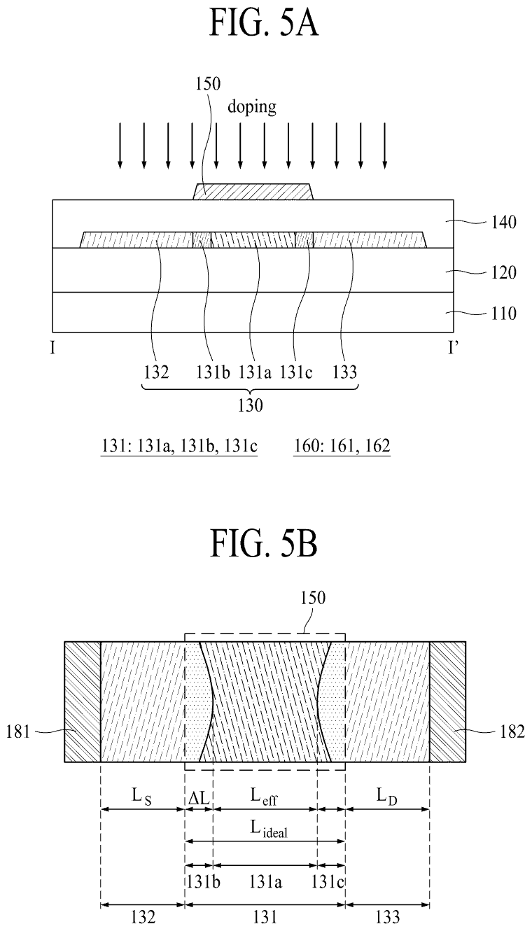

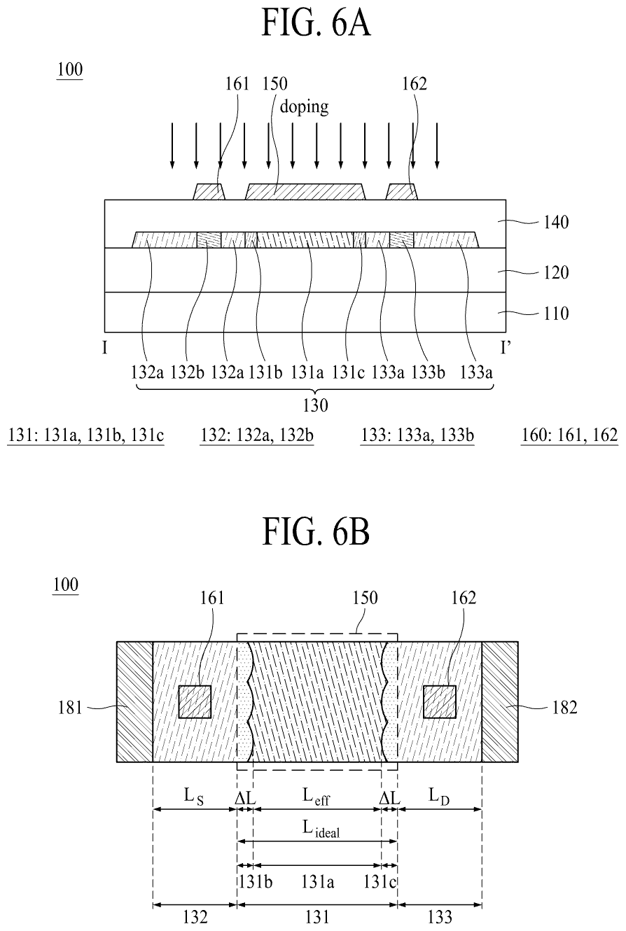

FIG. 5A is a schematic view illustrating conductorization of a thin film transistor according to a comparative example, and FIG. 5B is a schematic view illustrating a conductorization permeation depth ΔL of a thin film transistor according to a comparative example. Also, FIG. 6A is a schematic view illustrating conductorization of a thin film transistor according to one exemplary embodiment of the present disclosure, and FIG. 6B is a schematic view illustrating a conductorization permeation depth ΔL of a thin film transistor according to one exemplary embodiment of the present disclosure.

Hereinafter, the conductorization and effective channel length of the thin film transistor according to one exemplary embodiment of the present disclosure and the thin film transistor according to the comparative example will be described with reference to FIGS. 5A, 5B, 6A, and 6B.

Referring to FIG. 5A, selective conductorization with respect to the active layer 130 may be performed using the gate electrode 150 as a mask. For example, conductorization may be performed by dry etching, plasma treatment, or doping.

The first connection portion 132 and the second connection portion 133 may be formed by selective conductorization for the active layer 130 in accordance with the method shown in FIG. 5A. In this process, the channel portion 131 may be partially conductorized. For example, a region of the channel portion 131, which is adjacent to the first connection portion 132 or the second connection portion 133, may be conductorized. However, during the conductorization process, it is not easy to control the conductorization with respect to the edge of the channel portion 131 and the adjacent portion thereof.

A length or distance at which the channel portion 131 is conductorized during the conductorization process may be referred to as a conductorization permeation depth ΔL.

FIG. 5B is a schematic diagram illustrating a conductorization permeation depth ΔL.

In FIG. 5B, the length of the channel portion 131 of the active layer 130 overlapping the gate electrode 150 is indicated as “L_{ideal}”. “L_{ideal}” of FIG. 5B may be referred to as an ideal length of the channel portion 131. In FIG. 5B, “LS” refers to a length of the first connection portion 132 and “LD” refers to as a length of the second connection portion 133.

In the selective conductorization process for the active layer 130, a portion of the channel portion 131 is conductorized in accordance with diffusion of carriers, and the conductorized region does not function as a channel. In more detail, the first diffusion region 131b and the second diffusion region 131c, which are conductorized portions of the channel portion 131 as much as the conductorization permeation depth ΔL, are difficult to function as channels.

A region of the channel portion 131, which is not conductorized and may effectively serve as a channel, is referred to as the effective channel portion 131a, and a length of the effective channel portion 131a is referred to as an effective channel length L_{eff}. As the conductorization permeation depth ΔL increases, the effective channel length L_{eff} decreases.

In order for the thin film transistor to perform a switching role, the effective channel length L_{eff} needs to be maintained at a predetermined value or more. However, when a degree of conductorization with respect to the edge of the channel portion 131 cannot be controlled, it is difficult to design a width of the channel portion 131. For example, when considering a design error, in order to make sure of a predetermined effective channel length L_{eff}, the width of the channel portion 131 should be designed to be wide. In this case, the size of the thin film transistor may increase, and it may be difficult to miniaturize and integrate an element.

In addition, as the effective channel length L_{eff} decreases, if a sufficient effective channel length L_{eff} is not obtained, a negative (−) shift of a threshold voltage Vth of the thin film transistor may occur, which may reduce driving stability of the thin film transistor.

On the other hand, referring to FIG. 6A, the thin film transistor 100 according to one exemplary embodiment of the present disclosure may be selectively non-conductorized with respect to the active layer 130 using the gate electrode 150 and the barrier layer 160 arranged to be spaced apart from the gate electrode 150 as masks.

In more detail, in the process of forming the first connection portion 132 by conductorizing the active layer 130, the first non-doping portion 132b is formed in at least a portion of the first connection portion 132 by the first barrier layer 161. For example, the first non-doping portion 132b overlapping with the first barrier layer 161 is formed in at least a portion of the first connection portion 132. The first doping portion 132a is formed in a region not overlapping the first barrier layer 161 and the gate electrode 150. Also, in the process of forming the second connection portion 133 by conductorizing the active layer 130, the second non-doping portion 133b is formed in at least a portion of the second connection portion 133 by the second barrier layer 162. For example, the second non-doping portion 133b overlapping with the second barrier layer 162 is formed in at least a portion of the second connection portion 133. The second doping portion 133a is formed in a region not overlapping the second barrier layer 162.

In this process, for example, a region of the channel portion 131, which is adjacent to the first connection portion 132 and the second connection portion 133, may be partially conductorized by diffusion of carriers. However, permeation of the conductorized region into the edge of the channel portion 131 and the adjacent portion thereof may be partially suppressed by the non-doping portions 132b and 133b formed by the barrier layer 160.

According to one exemplary embodiment of the present disclosure, the first diffusion region 131b and the second diffusion region 131c of the channel portion 131 may be controlled by controlling the conductorization permeation depth ΔL using the barrier layer 160. Referring to FIGS. 6A and 6B, as the first non-doping portion 132b is formed in at least a portion of the first connection portion 132 by the first barrier layer 161, permeation of the conductorized region into the first side of the channel portion 131 may be partially suppressed, and thus the conductorization permeation depth ΔL may be shortened and the effective channel length L_{eff} may be improved. In addition, as the second non-doping portion 133b is formed in at least a portion of the second connection portion 133 by the second barrier layer 162, permeation of the conductorized region into the second side of the channel portion 131 may be partially suppressed, and the conductorization permeation depth ΔL may be shortened and the effective channel length L_{eff} may be improved.

Particularly, since the barrier layers 161 and 162 may be formed by the same method as the method of forming the gate electrode 150, the size and position of the barrier layer 160 may be precisely adjusted. As a result, the size and position of the non-doping portions 132b and 133b formed by the barrier layer 160 may be controlled, and the conductorization permeation depth ΔL of the channel portion 131 may be effectively controlled by the non-doping portions 132b and 133b formed at the appropriate size and position.

According to the embodiments of the present disclosure, since the conductorization permeation depth ΔL of the channel portion 131 may be controlled by the barrier layers 161 and 162 arranged on the gate insulating layer 140, a predetermined effective channel length L_{eff} may be obtained without designing the width of the channel portion 131 wide, which may be advantageous for miniaturization and integration of elements. Furthermore, as a predetermined effective channel length L_{eff} is obtained, a negative (−) shift of the threshold voltage Vth may hardly occur, whereby driving stability of the thin film transistor may be obtained.

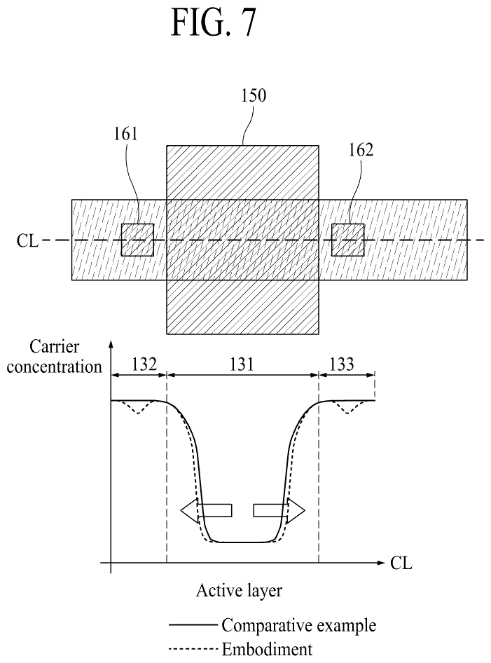

FIG. 7 is a graph for position-specific carrier concentration at a CL (Center Line) of an active layer of a thin film transistor 100 according to one exemplary embodiment of the present disclosure and a thin film transistor according to a comparative example.

In more detail, FIG. 7 is a graph showing the distribution of carrier concentration by location formed along the CL (center line) of the active layer 130 of the thin film transistor 100 according to an embodiment of the present disclosure and the thin film transistor according to the comparative example. The CL (center line) of the active layer 130 is a line that crosses the active layer 130 longitudinally. The longitudinal direction of the active layer 130 may refer to the direction in which current flows in the active layer 130.

In FIG. 7, the graph shown in the lower portion of FIG. 7 is a graph of carrier concentration distribution for a section of the active layer 130 that includes a region 132 overlapping with the first barrier layer 161, the channel portion 131 overlapping with the gate electrode 150, and a region 133 overlapping with the second barrier layer 162.

In FIG. 7, a period at which a carrier concentration decreases in a carrier concentration graph of the connection portions 132 and 133 means a carrier concentration of the non-doping portions 132b and 133b formed in the region overlapping the barrier layer 160. Also, in FIG. 7, a period of the first side and the second side of the channel portion 131, which show a carrier concentration that decreases rapidly and then does not decrease further after decreasing to a certain level in the carrier concentration graph of the channel portion 131, means the carrier concentration of the diffusion regions 131b and 131c formed by permeation of the conductorized region.

Referring to FIG. 7, the non-doping portions 132b and 133b formed in a region overlapping the barrier layer 160 have a higher carrier concentration than the channel portion 131.

According to one exemplary embodiment of the present disclosure, as doping is blocked by the barrier layer 160, the non-doping portions 132b and 133b have the same or similar carrier concentration as the channel portion 131 in which doping is blocked by the gate electrode 150 immediately after the doping process is performed. However, as time passes, the abundant carriers of the doping portions 132a and 133a surrounding the non-doping portions 132b and 133b on four surfaces are diffused toward the center of the non-doping portions 132b and 133b. Accordingly, the non-doping portions 132b and 133b have a higher carrier concentration than the channel portion 131 and lower carrier concentration than the doping portions 132a and 133a.

In more detail, the first non-doping portion 132b formed in the region overlapping the first barrier layer 161 has a higher carrier concentration than the channel portion 131, and the second non-doping portion 133b formed in the region overlapping the second barrier layer 162 has a higher carrier concentration than the channel portion 131.

The first connection portion 132 and the second connection portion 133 have a high carrier concentration due to doping. On the other hand, the channel portion 131 has a low carrier concentration because doping is blocked by the gate electrode 150. Accordingly, carriers may be diffused from the connection portions 132 and 133 having a high carrier concentration to the channel portion 131 having a low carrier concentration, and the diffusion regions 131b and 131c may be formed in the channel portion 131 by diffusion of carriers.

For example, the first diffusion region 131b and the second diffusion region 131c may be formed by diffusion of carriers from the two sides of the channel portion 131, which are in contact with the first connection portion 132 and the second connection portion 133, toward the center direction of the channel portion 131.

In more detail, the first diffusion region 131b may be formed by diffusion of carriers from the first side of the channel portion 131, which is in contact with the first connection portion 132, toward the center direction of the channel portion 131, and the second diffusion region 131c may be formed by diffusion of carriers from the second side of the channel portion 131, which is in contact with the second connection portion 133, toward the center direction of the channel portion 131.

Referring to FIG. 7, it may be confirmed that the thin film transistor 100 according to one exemplary embodiment of the present disclosure has a longer effective channel length L_{eff} than the thin film transistor according to the comparative example. Therefore, since the thin film transistor 100 according to one exemplary embodiment of the present disclosure has an effective channel portion 131a having a longer length compared to the thin film transistor according to the comparative example, it may be more advantageous for miniaturization and integration of elements.

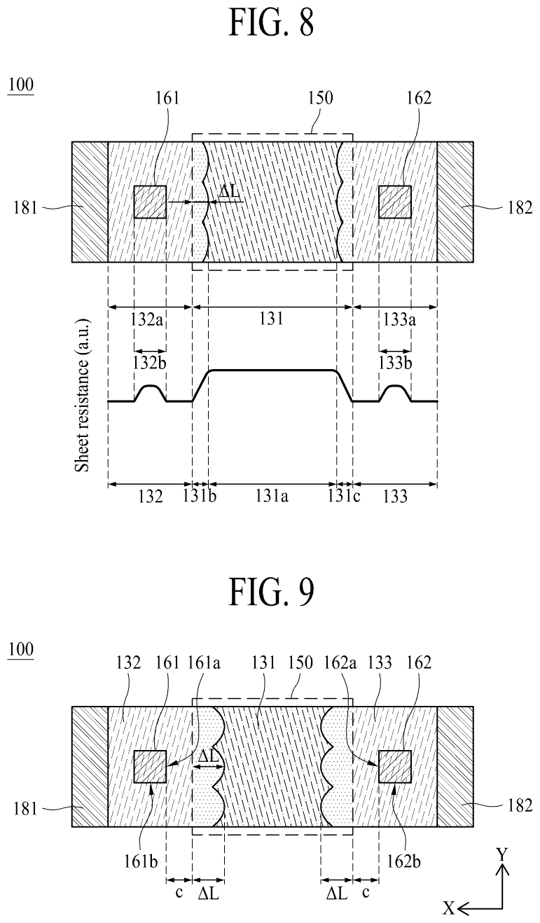

FIG. 8 is a graph illustrating position-specific sheet resistance distribution at a CL (Center Line) of an active layer of a thin film transistor 100 according to one exemplary embodiment of the present disclosure.

In detail, FIG. 8 shows position-specific sheet resistance at a CL (Center Line) of the active layer 130 in an off state of the thin film transistor 100 according to one exemplary embodiment of the present disclosure.

In more detail, FIG. 8 is a graph showing the distribution of sheet resistance by location formed along the CL (center line) of the active layer 130 in an off state of the thin film transistor 100 according to an embodiment of the present disclosure. The CL (center line) of the active layer 130 is a line that crosses the active layer 130 longitudinally. The longitudinal direction of the active layer 130 may refer to the direction in which current flows in the active layer 130.

In FIG. 8, the graph shown in the lower portion of FIG. 8 is a graph of sheet resistance distribution for a section of the active layer 130 that includes a region 132 overlapping with the first barrier layer 161, the channel portion 131 overlapping with the gate electrode 150, and a region 133 overlapping with the second barrier layer 162. Specifically, the section of the active layer 130 includes first non-doping portion 132b of a region 132 overlapping with the first barrier layer 161, the channel portion 131 overlapping with the gate electrode 150, and the second non-doping portion 133b of a region 133 overlapping with the second barrier layer 162.

Since the channel portion 131 has a lower carrier concentration than the connection portions 132 and 133, it has a higher sheet resistance than the connection portions 132 and 133 when the thin film transistor 100 is in an off state.

Since the connection portions 132 and 133 that are conductorized portions have a high carrier concentration, they have low sheet resistance. However, since the non-doping portions 132b and 133b of the connection portions 132 and 133 formed in the region overlapping the barrier layer 160 have a lower carrier concentration than the doping portions 132a and 133a, the non-doping portions 132b and 133b have higher sheet resistance than the doping portions 132a and 133a.

The carrier concentration of the first diffusion region 131b and the second diffusion region 131c of the channel portion 131 increases in a direction toward the connection portions 132 and 133 with respect to the effective channel portion 131a. Accordingly, the sheet resistance of the first diffusion region 131b of the channel portion 131 decreases in a direction from a portion, which is in contact with the effective channel portion 131a, toward the first connection portion 132, and the sheet resistance of the second diffusion region 131c decreases in a direction from a portion, which is in contact with the effective channel portion 131a, toward the second connection portion 133.

According to one exemplary embodiment of the present disclosure, the effective channel length may be stably obtained by controlling the conductorization permeation depth ΔL into the channel portion 131 through the barrier layer 160 arranged to be spaced apart from the gate electrode 150.

FIG. 9 is a schematic plan view illustrating a relation between a barrier layer of a thin film transistor and a conductorization permeation depth ΔL according to one exemplary embodiment of the present disclosure.

According to one exemplary embodiment of the present disclosure, the barrier layer 160 has a first line segment 160a and a second line segment 160b. For example, each of the first barrier layer 161 and the second barrier layer 162 of the barrier layer 160 has a first line segment and a second line segment. Specifically, the first barrier layer 161 has the first line segment 161a and the second line segment 161b, and the second barrier layer 162 has the first line segment 162a and the second line segment 162b.

Referring to FIG. 9, the first line segment 160a of the barrier layer 160 refers to a side facing the gate electrode 150 among line segments defining a surface in which the barrier layer 160 is in contact with the gate insulating layer 140. The second line segment 160b of the barrier layer 160 refers to a side intersecting the first line segment 160a of the barrier layer 160.

In more detail, the first line segment 161a of the first barrier layer 161 refers to a side facing the gate electrode 150 among the line segments defining the surface in which the first barrier layer 161 is in contact with the gate insulating layer 140, and the second line segment 161b of the first barrier layer 161 refers to a side intersecting the first line segment 161a of the first barrier layer 161. In addition, a first line segment 162a of the second barrier layer 162 refers to a side facing the gate electrode 150 among line segments defining a surface in which the second barrier layer 162 is in contact with the gate insulating layer 140, a second line segment 162b of the second barrier layer 162 refers to a side intersecting the first line segment 162a of the second barrier layer 162.

For example, the length of each of the first line segment and the second line segment of the first barrier layer 161 and the second barrier layer 162 ranges from 1.5 μm to 2.5 μm, but is not limited thereto.

According to one exemplary embodiment of the present disclosure, a length of the first line segment 160 a of the barrier layer 160 may range from 1.5 μm to 2.5 μm, and a length of the second line segment 160 b of the barrier layer 160 may range from 1.5 μm to 2.5 μm, but is not limited thereto. In more detail, a length of the first line segment 161a of the first barrier layer 161 may range from 1.5 μm to 2.5 μm, and a length of the second line segment 161 b of the first barrier layer 161 may range from 1.5 μm to 2.5 μm. Also, a length of the first line segment 162 a of the second barrier layer 162 may range from 1.5 μm to 2.5 μm, and a length of the second line segment 162 b of the second barrier layer 162 may range from 1.5 μm to 2.5 μm.

The length of the first line segment 160a of the barrier layer 160 may be the same as or different from the length of the second line segment 160b. A shape and area of the barrier layer 160 may vary depending on the length of the first line segment 160a and the length of the second line segment 160b of the barrier layer 160.

According to one exemplary embodiment of the present disclosure, the length of the first line segment 160a of the barrier layer 160 may be the same as the length of the second line segment 160b of the barrier layer 160.

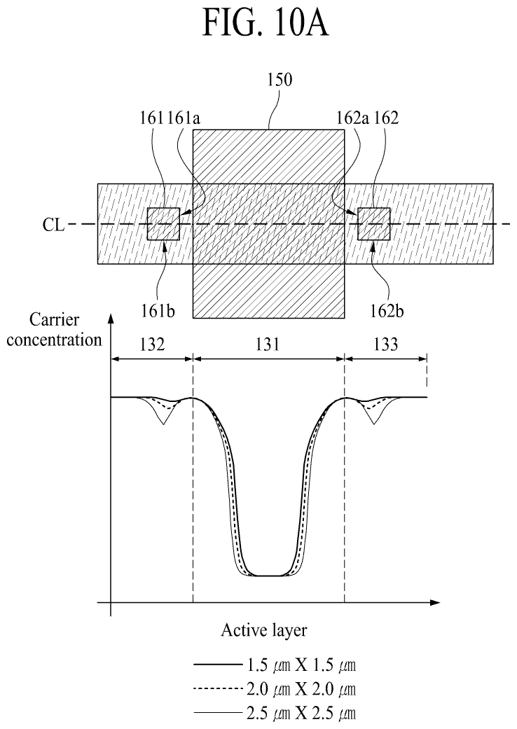

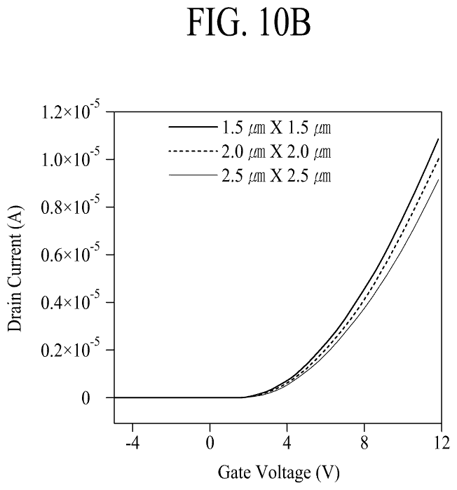

FIG. 10A is a graph for position-specific carrier concentration at a CL (Center Line) of an active layer 130 according to each area of a barrier layer 160 of a thin film transistor 100 according to one exemplary embodiment of the present disclosure, and FIG. 10B is a current graph for each area of a barrier layer 160.

In more detail, FIG. 10A is a graph showing the distribution of carrier concentration by location formed along the CL (center line) of the active layer 130 according to each area of a barrier layer 160. The CL (center line) of the active layer 130 is a line that crosses the active layer 130 longitudinally. The longitudinal direction of the active layer 130 may refer to the direction in which current flows in the active layer 130.

In FIG. 10A, the graph shown in the lower portion of FIG. 10A is a graph of carrier concentration distribution for a section of the active layer 130 that includes a region 132 overlapping with the first barrier layer 161, the channel portion 131, and a region 133 overlapping with the second barrier layer 162. Specifically, the section of the active layer 130 includes first non-doping portion 132b of a region 132 overlapping with the first barrier layer 161, the channel portion 131 overlapping with the gate electrode 150, and the second non-doping portion 133b of a region 133 overlapping with the second barrier layer 162.

In FIG. 10A, a thin solid line is a carrier concentration graph of the thin film transistor 100 in which a length of each of the first line segment 160a and the second line segment 160 b of the barrier layer 160 is 2.5 μm, a broken line is a carrier concentration graph of the thin film transistor 100 in which a length of each of the first line segment 160a and the second line segment 160 b of the barrier layer160 is 2.0 μm, and a thick solid line is a carrier concentration graph of the thin film transistor 100 in which a length of each of the first line segment 160a and the second line segment 160 b of the barrier layer160 is 1.5 μm.

Referring to FIGS. 10A and 10B, for example, as an area of the barrier layer 160 increases, the conductorization permeation depth ΔL into the channel portion 131 may decrease, whereby the length of the effective channel portion 131a of the channel portion 131 may increase. However, when the area of the barrier layer 160 increases, the area of the non-doping portions 132b and 133b included in the connection portions 132 and 133 increases, and thus resistance of the connection portions 132 and 133 increases, whereby current loss may occur.

When the length of each of the first line segment 160a and the second line segment 160 b of the barrier layer 160 is less than 1.5 μm, the non-doping portions 132 b and 133 b do not obtain a sufficient area, and thus it may be difficult to control the conductorization permeation depth ΔL. When the length of each of the first line segment 160a and the second line segment 160 b of the barrier layer 160 is greater than 3.0 μm, resistance of the connection portions 132 and 133 may increase as the area of the non-doping portions 132b and 133b increases. Therefore, it may be difficult for the connection portions 132 and 133 to function as the line portions. In this way, the length of each of the first line segment 160a and the second line segment 160 b of the barrier layer 160 may range from 1.5 μm and 3.0 μm, but is not limited thereto. For example, the length of each of the first line segment and the second line segment of the first barrier layer 161 and the second barrier layer 162 may range from 1.5 μm to 2.5 μm, but is not limited thereto.

When the length of the first line segment 160a of the barrier layer 160 is less than 1.5 μm, the non-doping portions 132 b and 133 b do not obtain a sufficient area, and thus it may be difficult to control the conductorization permeation depth ΔL.

When the length of the first line segment 160a of the barrier layer 160 is greater than 3.0 μm, resistance of the connection portions 132 and 133 may increase as the area of the non-doping portions 132b and 133b increases. Therefore, it may be difficult for the connection portions 132 and 133 to function as the line portions.

When the length of the second line segment 160b of the barrier layer 160 is less than 1.5 μm, the non-doping portions 132 b and 133 b do not obtain a sufficient area, and thus it may be difficult to control the conductorization permeation depth ΔL.

When the length of the second line segment 160b of the barrier layer 160 is greater than 3.0 μm, resistance of the connection portions 132 and 133 increases as the area of the non-doping portions 132b and 133b increases, and the connection portions 132 and 133 are arranged to be longer than necessary in Y-axis direction, thereby interrupting the flow of current. Therefore, it may be difficult for the connection portions 132 and 133 to function as the line portions.

According to one exemplary embodiment of the present disclosure, the barrier layer 160 is arranged to be spaced apart from the gate electrode 150 by a certain distance.

Referring to FIG. 9, a spaced distance ‘c’ between the barrier layer 160 and the gate electrode 150 means a distance from the end of the gate electrode 150 to the first line segment 160a of the barrier layer 160 based on the end of the first side or the second side of the gate electrode 150.

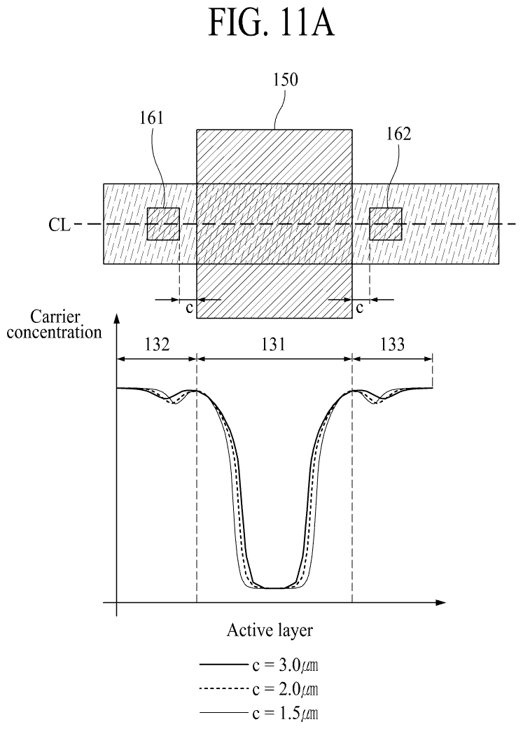

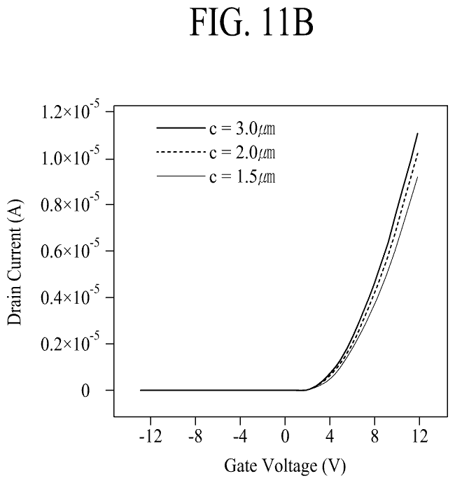

FIG. 11A is a graph for position-specific carrier concentration at a CL (Center Line) of an active layer according to each spaced distance between a barrier layer 160 and a gate electrode 150 of a thin film transistor 100 according to one exemplary embodiment of the present disclosure, and FIG. 11B is a current graph for each spaced distance from the barrier layer 160 and the gate electrode 150.

In more detail, FIG. 11A is a graph showing the distribution of carrier concentration by location formed along the CL (center line) of the active layer 130 according to each spaced distance between a barrier layer 160 and a gate electrode 150. The CL (center line) of the active layer 130 is a line that crosses the active layer 130 longitudinally. The longitudinal direction of the active layer 130 may refer to the direction in which current flows in the active layer 130.

In FIG. 11A, the graph shown in the lower portion of FIG. 11A is a graph of carrier concentration distribution for a section of the active layer 130 that includes a region 132 overlapping with the first barrier layer 161 overlapping with the gate electrode 150, the channel portion 131, and a region 133 overlapping with the second barrier layer 162.

In FIG. 11A, a thin solid line is a carrier concentration graph of the thin film transistor 100 in which a spaced distance between the barrier layer 160 and the gate electrode 150 is 1.5 μm, a broken line is a carrier concentration graph of the thin film transistor 100 in which a spaced distance between the barrier layer 160 and the gate electrode 150 is 2.0 μm, and a thick solid line is a carrier concentration graph of the thin film transistor 100 in which a spaced distance between the barrier layer 160 and the gate electrode 150 is 3.0 μm.

Referring to FIGS. 11A and 11B, as the spaced distance between the barrier layer 160 and the gate electrode 150 becomes shorter, the conductorization permeation depth ΔL into the channel portion 131 may be shorter, and thus the length of the effective channel portion 131a of the channel portion 131 may be longer. However, when the spaced distance between the barrier layer 160 and the gate electrode 150 is shorter, the non-doping portions 132b and 133b are formed closer to the channel portion 131 to interrupt the flow of current, and resistance of the connection portions 132 and 133 may increase, thereby causing current loss.

According to one exemplary embodiment of the present disclosure, the length of the first line segment 160a and the length of the second line segment 160b of the barrier layer 160 may be different from each other.

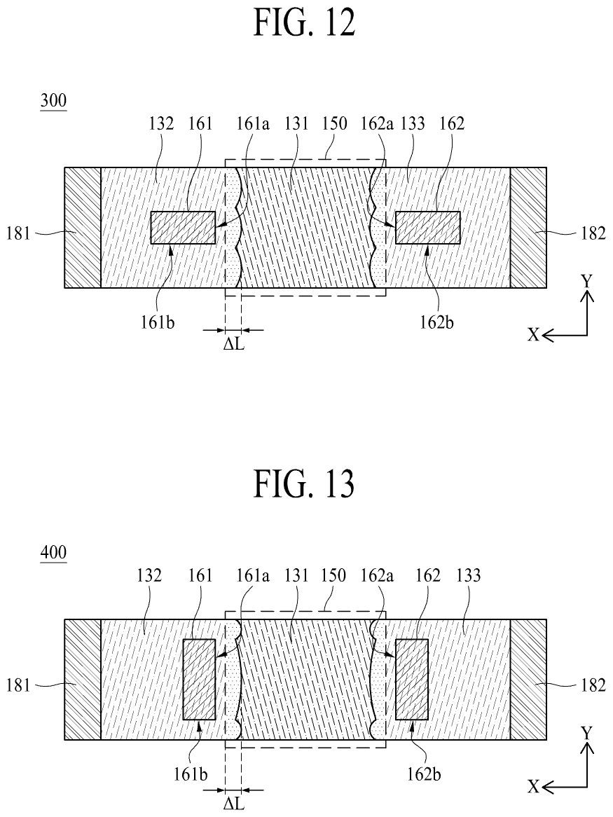

The thin film transistors 300 and 400 according to another exemplary embodiment of the present disclosure in which the length of the first line segment 160a of the barrier layer 160 and the length of the second line segment 160b of the barrier layer 160 are different from each other may include, for example, a barrier layer 160 arranged as shown in FIGS. 12 and 13.

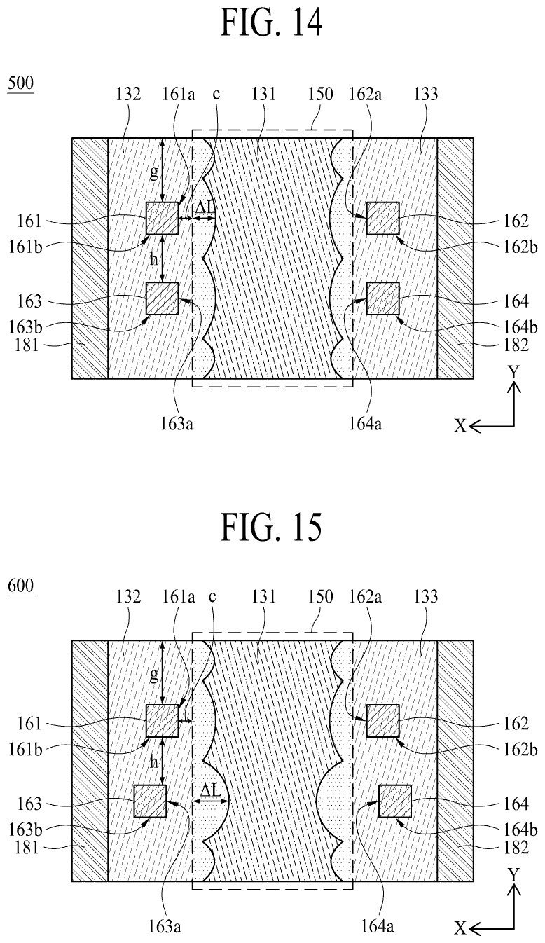

FIGS. 14 to 16 are schematic views illustrating thin film transistors 500, 600, and 700 and a conductorization permeation region according to another exemplary embodiment of the present disclosure.

Hereinafter, to avoid redundancy, descriptions of already described components will be omitted or briefly described.

According to another exemplary embodiment of the present disclosure, a thin film transistor may include a gate electrode 150 on a gate insulating layer 140 and a first barrier layer 161 on the gate insulating layer 140, and the first barrier layer 161 may further include at least one sub-barrier layer 163.

In more detail, the first barrier layer 161 may further include one first sub-barrier layer 163, and may further include a plurality of first sub-barrier layers 163, for example, two or more first sub-barrier layers 163, if necessary.

According to another exemplary embodiment of the present disclosure, the first sub-barrier layer 163 may be arranged in the source region, for example. Also, the first sub-barrier layer 163 may not be electrically connected to the gate electrode 150.

Referring to FIGS. 14 to 16, the gate electrode 150 and the first barrier layer 161 are arranged to be spaced apart from each other, the gate electrode 150 and the first sub-barrier layer 163 are arranged to be spaced apart from each other, and the first barrier layer 161 and the first sub-barrier layer 163 are also arranged to be spaced apart from each other.

The first barrier layer 161 and the first sub-barrier layer 163 may be arranged to be spaced apart from each other in the Y-axis direction. When a plurality of first sub-barrier layers 163 are provided, the first barrier layer 161 and each of the plurality of first sub-barrier layers 163 may be arranged to be spaced apart from each other in the Y-axis direction, and the plurality of first sub-barrier layers 163 may be arranged to be spaced apart from each other in the Y-axis direction.

The gate electrode 150 and the first barrier layer 161 may be arranged to be spaced apart from each other in the X-axis direction, and the gate electrode 150 and the first sub-barrier layer 163 may be arranged to be spaced apart from each other in the X-axis direction. Referring to FIG. 14, the first barrier layer 161 and the first sub-barrier layer 163 may be arranged to correspond to each other in Y-axis direction. Referring to FIG. 15, the first sub-barrier layer 163 may be offset from the first barrier layer 161 in the X-axis direction, but is not limited thereto.

The first barrier layer 161 may overlap a portion of the active layer 130, and the first sub-barrier layer 163 may overlap another portion of the active layer 130.

According to another exemplary embodiment of the present disclosure, the first connection portion 132 may include a first doping portion 132a that is in contact with the first side of the channel portion 131, a first non-doping portion 132b formed in an island shape of four surfaces surrounded by the first doping portion 132a, and a third non-doping portion 132c spaced apart from the first non-doping portion 132b and formed in an island shape of four surfaces surrounded by the first doping portion 132a.

The first non-doping portion 132b does not overlap the gate electrode 150, but overlaps the first barrier layer 161. The third non-doping portion 132c does not overlap the gate electrode 150, but overlaps the first sub-barrier layer 163. When viewed in a plan view, the third non-doping portion 132c may be arranged to be spaced apart from the first diffusion region 131b in a shape surrounded by the first doping portion 132a. In addition, the third non-doping portion 132c may be arranged to be spaced apart from the first non-doping portion 132b in the Y-axis direction in a shape surrounded by the first doping portion 132a.

According to another exemplary embodiment of the present disclosure, the first sub-barrier layer 163 has a first line segment 163a and a second line segment 163b.

Referring to FIG. 14, the first line segment 163a of the first sub-barrier layer 163 refers to a side facing the gate electrode 150 among line segments defining a surface in which the first sub-barrier layer 163 and the gate insulating layer 140 are in contact with each other. The second line segment 163b of the first sub-barrier layer 163 refers to a side intersecting the first line segment 163a of the first sub-barrier layer 163.

A length of the first line segment 163a of the first sub-barrier layer 163 may range from 1.5 μm to 2.5 μm, and a length of the second line segment 163 b of the first sub-barrier layer 163 may range from 1.5 μm to 2.5 μm. The length of the first line segment 163 a of the first sub-barrier layer 163 may be the same as or different from the length of the second line segment 163b of the first sub-barrier layer 163.

Referring to FIG. 14, a spaced distance between the first barrier layer 161 and the gate electrode 150 may be the same as a spaced distance between the first sub-barrier layer 163 and the gate electrode 150, but is not limited thereto.

Referring to FIG. 15, the spaced distance between the first barrier layer 161 and the gate electrode 150 may be different from the spaced distance between the first sub-barrier layer 163 and the gate electrode 150. For example, the spaced distance between the first barrier layer 161 and the gate electrode 150 may be smaller than the spaced distance between the first sub-barrier layer 163 and the gate electrode 150.

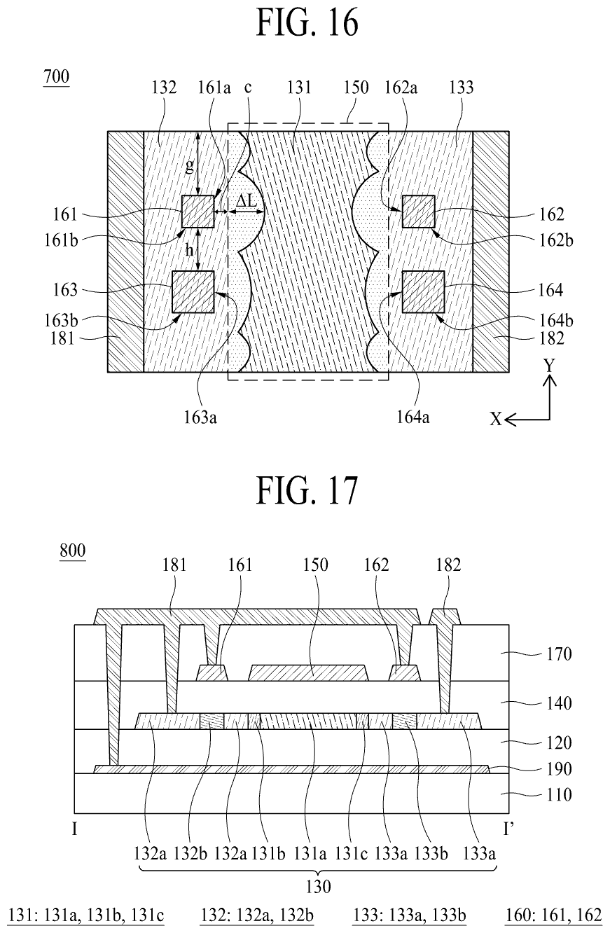

Referring to FIG. 16, a length of at least one of the first line segment 161a or the second line segment 161b of the first barrier layer 161 may be different from the length of at least one of the first line segment 163a or the second line segment 163b of the first sub-barrier layer 163. Therefore, an area of the first barrier layer 161 may be different from an area of the first sub-barrier layer 163.

Referring to FIGS. 14 to 16, the first barrier layer 161 may be, for example, arranged to be spaced apart from an upper end of the first connection portion 132 by a certain distance or more based on the Y-axis direction on a plane.

When the first barrier layer 161 is arranged close to the upper end of the first connection portion 132 by a certain distance or less, it may be difficult to control the conductorization permeation depth ΔL of the first side of the channel portion 131. This equally applies to the case when the first sub-barrier layer 163 is arranged close to a lower end of the first connection portion 132.

Therefore, a spaced distance ‘g’ between the first barrier layer 161 and the upper end of the first connection portion 132 may be, for example, in the range of 1.5 μm to 2.5 μm. In more detail, the spaced distance ‘g’ between the first barrier layer 161 and the upper end of the first connection portion 132 may be, for example, in the range of 1.5 μm to 2.0 μm, but is not limited thereto.

Therefore, a spaced distance between the first sub-barrier layer 163 and the lower end of the first connection portion 132 may be, for example, in the range of 1.5 μm to 2.5 μm. In more detail, the spaced distance between the first sub-barrier layer 163 and the lower end of the first connection portion 132 may be, for example, in the range of 1.5 μm to 2.0 μm, but is not limited thereto.

Referring to FIGS. 14 to 16, the first barrier layer 161 may be, for example, arranged to be spaced apart from the first sub-barrier layer 163 by a certain distance or more based on the Y-axis direction on a plane.

When the first barrier layer 161 is arranged close to the first sub-barrier layer 163 by a certain distance or less, the same effect as when the first barrier layer 161 and the first sub-barrier layer 163 are connected may occur. For this reason, resistance of the first connection portion 132 may increase, resulting in current loss.

Accordingly, a spaced distance ‘h’ between the first barrier layer 161 and the first sub-barrier layer 163 may be, for example, in the range of 1.5 μm to 2.5 μm. In more detail, the spaced distance ‘h’ between the first barrier layer 161 and the first sub-barrier layer 163 may be, for example, in the range of 1.5 μm to 2.0 μm.

According to another exemplary embodiment of the present disclosure, a thin film transistor may include a gate electrode 150 on the gate insulating layer 140 and a second barrier layer 162 on the gate insulating layer 140, and the second barrier layer 162 may further include at least one second sub-barrier layer 164.

In more detail, the second barrier layer 162 may further include one second sub-barrier layer 164, and may further include a plurality of second sub-barrier layers 164, for example, two or more second sub-barrier layers 164, if necessary.

According to another exemplary embodiment of the present disclosure, the second sub-barrier layer 164 may be arranged in the drain region, for example. Also, the second sub-barrier layer 164 may not be electrically connected to the gate electrode 150.

Referring to FIGS. 14 to 16, the gate electrode 150 and the first barrier layer 161 are arranged to be spaced apart from each other, the gate electrode 150 and the first sub-barrier layer 163 are arranged to be spaced apart from each other, the gate electrode 150 and the second sub-barrier layer 164 are arranged to be spaced apart from each other, and the second barrier layer 162 and the second sub-barrier layer 164 are also arranged to be spaced apart from each other.

The second barrier layer 162 and the second sub-barrier layer 164 may be arranged to be spaced apart from each other in the Y-axis direction. When a plurality of second sub-barrier layers 164 are provided, the second barrier layer 162 and each of the plurality of second sub-barrier layers 164 may be arranged to be spaced apart from each other in the Y-axis direction.

Referring to FIG. 16, the second barrier layer 162 and the second sub-barrier layer 164 may be arranged to correspond to each other in Y-axis direction. Referring to FIG. 15, the first sub-barrier layer 163 may be offset from the first barrier layer 161 in the X-axis direction, but is not limited thereto.

The second barrier layer 162 may overlap a portion of the active layer 130, and the second sub-barrier layer 164 may overlap another portion of the active layer 130.

According to another exemplary embodiment of the present disclosure, the second connection portion 133 may include a second doping portion 133a that is in contact with the second side of the channel portion 131, a second non-doping portion 133b formed in an island shape of four surfaces surrounded by the second doping portion 133a, and a fourth non-doping portion 133c spaced apart from the second non-doping portion 133b and formed in an island shape of four surfaces surrounded by the second doping portion 133a.

The first non-doping portion 132b does not overlap the gate electrode 150, but overlaps the first barrier layer 161. The fourth non-doping portion 133c does not overlap the gate electrode 150, but overlaps the second sub-barrier layer 164. When viewed in a plan view, the fourth non-doping portion 133c may be arranged to be spaced apart from the second diffusion region 131c in a shape surrounded by the second doping portion 133a. Also, the fourth non-doping portion 133c may be arranged to be spaced apart from the second non-doping portion 133b in the Y-axis direction in a shape surrounded by the second doping portion 133a.

According to another exemplary embodiment of the present disclosure, the second sub-barrier layer 164 has a first line segment 164a and a second line segment 164b.

Referring to FIG. 14, the first line segment 164a of the second sub-barrier layer 164 refers to a side facing the gate electrode 150 among line segments defining a surface in which the second sub-barrier layer 164 and the gate insulating layer 140 are in contact with each other. The second line segment 164b of the second sub-barrier layer 164 refers to a side intersecting the first line segment 164a of the second sub-barrier layer 164.

A length of the first line segment 164a of the second sub-barrier layer 164 may range from 1.5 μm to 2.5 μm, and a length of the second line segment 164 b of the second sub-barrier layer 164 may range from 1.5 μm to 2.5 μm. The length of the first line segment 164 a of the second sub-barrier layer 164 may be the same as or different from the length of the second line segment 164b of the second sub-barrier layer 164.

Referring to FIG. 14, a spaced distance between the second barrier layer 162 and the gat electrode 150 may be the same as a spaced distance between the second sub-barrier layer 164 and the gate electrode 150.

Referring to FIG. 15, the spaced distance between the second barrier layer 162 and the gate electrode 150 may be different from the spaced distance between the second sub-barrier layer 164 and the gate electrode 150. For example, the spaced distance between the second barrier layer 162 and the gate electrode 150 may be smaller than the spaced distance between the second sub-barrier layer 164 and the gate electrode 150.

Referring to FIG. 16, a length of at least one of the first line segment 162a or the second line segment 162b of the second barrier layer 162 may be different from the length of at least one of the first line segment 164a or the second line segment 164b of the second sub-barrier layer 164. Accordingly, an area of the second barrier layer 162 may be different from an area of the second sub-barrier layer 164.

Referring to FIGS. 14 to 16, the second barrier layer 162 may be, for example, arranged to be spaced apart from an upper end of the second connection portion 133 by a certain distance or more based on the Y-axis direction on a plane.

When the second barrier layer 162 is arranged close to the upper end of the second connection portion 133 by a certain distance or less, it may be difficult to control the conductorization permeation depth ΔL of the second side of the channel portion 131. This equally applies to the case when the second sub-barrier layer 164 is arranged close to a lower end of the second connection portion 133.

Therefore, a spaced distance ‘g’ between the second barrier layer 162 and the upper end of the second connection portion 133 may be, for example, in the range of 1.5 μm to 2.5 μm. In more detail, the spaced distance ‘g’ between the second barrier layer 162 and the upper end of the second connection portion 133 may be, for example, in the range of 1.5 μm to 2.0 μm, but is not limited thereto.

Therefore, a spaced distance between the second sub-barrier layer 164 and the lower end of the second connection portion 133 may be, for example, in the range of 1.5 μm to 2.5 μm. In more detail, the spaced distance between the second sub-barrier layer 164 and the lower end of the second connection portion 133 may be, for example, in the range of 1.5 μm to 2.0 μm, but is not limited thereto.

Referring to FIGS. 14 to 16, the second barrier layer 162 may be, for example, arranged to be spaced apart from the second sub-barrier layer 164 by a certain distance or more based on the Y-axis direction on a plane.

When the second barrier layer 162 is arranged close to the second sub-barrier layer 164 by a certain distance or less, the same effect as when the second barrier layer 162 and the second sub-barrier layer 164 are connected may occur. For this reason, resistance of the second connection portion 133 may increase, resulting in current loss.

Accordingly, a spaced distance ‘h’ between the second barrier layer 162 and the second sub-barrier layer 164 may be, for example, in the range of 1.5 μm to 2.5 μm. In more detail, the spaced distance ‘h’ between the second barrier layer 162 and the second sub-barrier layer 164 may be, for example, in the range of 1.5 μm to 2.0 μm.

The thin film transistors 500, 600 and 700 according to another exemplary embodiment of the present disclosure, which include the sub-barrier layers 163 and 164, may include, for example, barrier layers 161 and 162 and sub-barrier layers 163 and 164, which are arranged as shown in FIGS. 14 and 16.

FIG. 17 is a schematic cross-sectional view illustrating a thin film transistor 800 according to further embodiments of the present disclosure.

Referring to FIG. 17, a light shielding layer 190 may be arranged on the substrate 110. The light shielding layer 190 has light shielding characteristics. The light shielding layer 190 may shield light incident from the substrate 110 to protect the channel portion 131 of the active layer 130.

The light shielding layer 190 may be made of a material having light shielding characteristics. The light shielding layer 190 may include at least one of an aluminum-based metal such as aluminum (Al) or an aluminum alloy, a molybdenum-based metal such as molybdenum (Mo) or a molybdenum alloy, chromium (Cr), tantalum (Ta), neodymium (Nd), titanium (Ti), or iron (Fe).

According to one exemplary embodiment of the present disclosure, the light shielding layer 190 may have electrical conductivity. The light shielding layer 190 may be electrically connected to any one of the source electrode 181 and the drain electrode 182. Referring to FIG. 17, the light shielding layer 190 may be connected to the source electrode 181.

The buffer layer 120 is arranged on the light shielding layer 190. The buffer layer 120 covers the upper surface of the substrate 110 and an upper surface of the light shielding layer 190. The buffer layer 120 has insulation properties and protects the active layer 130.

Referring to FIG. 17, the active layer 130 may be arranged on the buffer layer 120.

Hereinafter, a method of manufacturing a thin film transistor according to another exemplary embodiment of the present disclosure will be described.

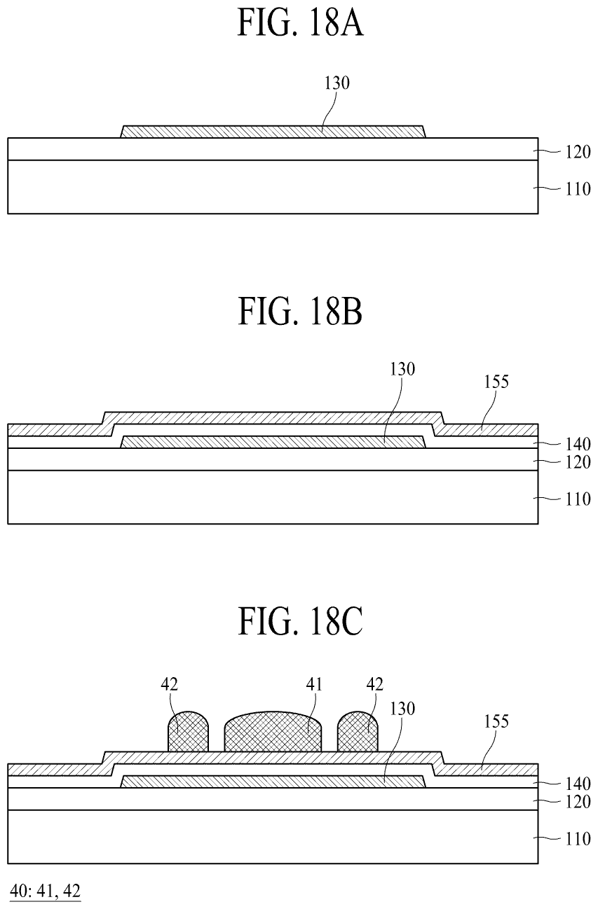

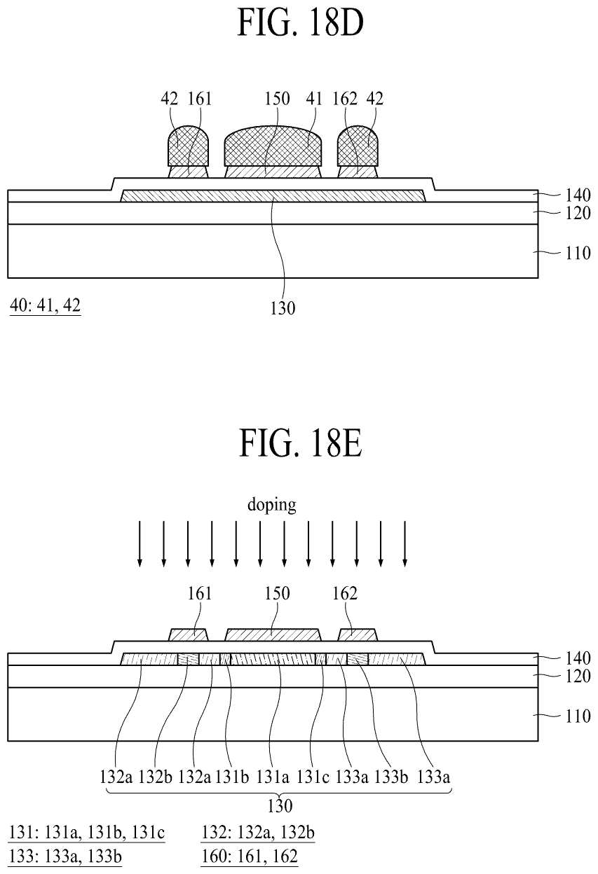

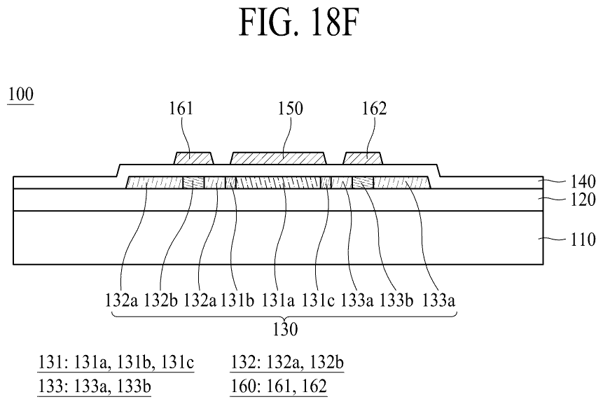

FIGS. 18A to 18F are schematic cross-sectional views illustrating a method of manufacturing a thin film transistor 100 according to further embodiments of the present disclosure.

First, referring to FIG. 18A, an active layer 130 is formed on a substrate 110. Next, a gate insulating layer 140 is formed on the active layer 130.

Referring to FIG. 18A, a buffer layer 120 is formed on the substrate 110, and the active layer 130 is formed on the buffer layer 120. The active layer 130 includes an oxide semiconductor material. In more detail, the active layer 130 may be an oxide semiconductor layer.

Referring to FIG. 18B, the gate insulating layer 140 is formed on the active layer 130, and a gate electrode material layer 155 is formed on the gate insulating layer 140. The gate electrode material layer 155 may include a metal.

Referring to FIG. 18C, a photoresist pattern 40 is formed on the gate electrode material layer 155. The photoresist pattern 40 includes a first photoresist pattern 41 and a second photoresist pattern 42. For example, the second photoresist pattern 42 may comprise tweo second photoresist patterns 42, and the first photoresist pattern 41 may be disposed between two second photoresist patterns 42.

The photoresist pattern 40 may be made by coating, exposing and developing a photoresist on an entire surface of the gate electrode material layer 155.

Referring to FIG. 18D, the gate electrode material layer 155 is etched using the photoresist pattern 40 as a mask. As a result, a gate electrode 150, a first barrier layer 161, and a second barrier layer 162 are formed. For example, the gate electrode 150 is etched using the first photoresist pattern 41, the first barrier layer 161 is etched using one of the two second photoresist patterns 42, and the second barrier layer 162 is etched using the other of the two second photoresist patterns 42.

As shown in FIG. 18D, an area of the first photoresist pattern 41 corresponds to an area of the gate electrode 150 on a plane. An area of the second photoresist pattern 42 corresponds to an area of the first barrier layer 161 and the second barrier layer 162 on a plane. The gate electrode 150 may be arranged within an area defined by the first photoresist pattern 41 on a plane. The first barrier layer 161 and the second barrier layer 162 may be arranged within an area defined by the second photoresist pattern 42 on a plane. The gate insulating layer 140 covers an entire upper surface of the active layer 130.

As shown in FIGS. 18B to 18D, the step of forming the gate electrode 150 and the barrier layer 160 includes the step of forming the gate electrode material layer 155 on the gate insulating layer 140 (FIG. 18B), the step of forming the first photoresist pattern 41 and the second photoresist pattern 42 on the gate electrode material layer 155 (FIG. 18C), and the step of etching the gate electrode material layer 155 using the first photoresist pattern 41 and the second photoresist pattern 42 as masks (FIG. 18D).

Referring to FIG. 18E, after the photoresist pattern 40 is removed, the active layer 130 is doped with a dopant.

The dopant may include at least one of boron (B), phosphorus (P), fluorine (F), or hydrogen (H).

In the doping process of the dopant, the gate electrode 150 and the barrier layer 160 function as masks. Referring to FIG. 18E, a region of the active layer 130, which is not protected by the gate electrode 150 and the barrier layer 160, is selectively doped.

Referring to FIG. 18E, doping portions 132a and 133a are formed in connection portions 132 and 133 by doping, a channel portion 131 is formed in a region that is not doped by the gate electrode 150, and non-doping portions 132b and 133b are formed in a region that is not doped by the barrier layer 160. For example, the non-doping portion 132b is formed in a region that is not doped by the first barrier layer 161, and the non-doping portion 133b is formed in a region that is not doped by the second barrier layer 162.

Referring to FIG. 18F, the active layer 130 includes a channel portion 131 overlapping the gate electrode 150, a first non-doping portion 132b overlapping the first barrier layer 161, a first doping portion 132a not overlapping the gate electrode 150 and the first barrier layer 161, a second non-doping portion 133b overlapping the second barrier layer 162, and a second doping portion 133a not overlapping the gate electrode 150 and the second barrier layer 162.

The thin film transistor 100 according to one exemplary embodiment of the present disclosure may be formed by the above process.

Another embodiment of the present disclosure provides a display device 900 that includes the above-described thin film transistors 100, 200, 300, 400, 500, 600, 700 and 800.

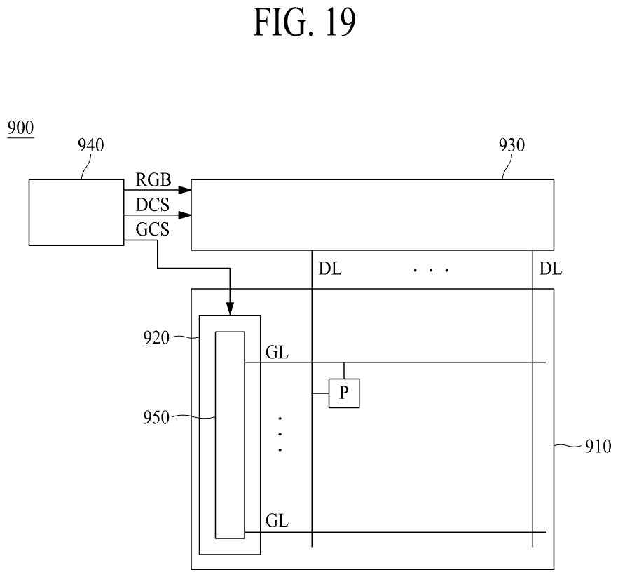

FIG. 19 is a schematic view illustrating a display device 900 according to further embodiment of the present disclosure.

As shown in FIG. 19, the display device 900 according to further embodiment of the present disclosure may include a display panel 910, a gate driver 920, a data driver 930 and a controller 940, and other circuit components.

The display panel 910 includes gate lines GL and data lines DL, and pixels P are arranged in intersection regions of the gate lines GL and the data lines DL. An image is displayed by driving of the pixels P.

The plurality of data lines DL and the plurality of gate lines GL may intersect one another. Each of the plurality of data lines DL may be configured to extend in a first direction. Each of the plurality of gate lines GL may be configured to extend in a second direction different from the first direction.

The controller 940 controls the gate driver 920 and the data driver 930.

The controller 940 outputs a gate control signal GCS for controlling the gate driver 920 and a data control signal DCS for controlling the data driver 930 by using a signal supplied from an external system. Also, the controller 940 samples input image data input from the external system, realigns the sampled data and supplies the realigned digital image data RGB to the data driver 930.

The gate control signal GCS includes a gate start pulse GSP, a gate shift clock GSC, a gate output enable signal GOE, a start signal Vst and a gate clock GCLK. Also, control signals for controlling a shift register 950 may be included in the gate control signal GCS.

The data control signal DCS includes a source start pulse SSP, a source shift clock signal SSC, a source output enable signal SOE and a polarity control signal POL.

The data driver 930 supplies a data voltage to the data lines DL of the display panel 910 according to driving timing control of the controller 940. In detail, the data driver 930 converts the image data RGB input from the controller 940 into an analog data voltage and supplies the data voltage to the data lines DL.

The gate driver 920 may include a shift register 950.

The shift register 950 sequentially supplies gate pulses to the gate lines GL for one frame by using the start signal and the gate clock, which are transmitted from the controller 940. In this case, one frame means a time period at which one image is output through the display panel 910. The gate pulse has a turn-on voltage capable of turning on a switching element (thin film transistor) arranged in the pixel P.

Also, the shift register 950 supplies a gate-off signal capable of turning off the switching element, to the gate line GL for the other period of one frame, at which the gate pulse is not supplied. Hereinafter, the gate pulse and the gate-off signal will be collectively referred to as a scan signal SS or Scan.

According to one exemplary embodiment of the present disclosure, the gate driver 920 may be packaged on the substrate 110. In this way, a structure in which the gate driver 920 is directly packaged on the substrate 110 will be referred to as a Gate In Panel (GIP) structure. The gate driver 920 may include at least one of the above-described thin film transistors 100, 200, 300, 400, 500, 600, 700 and 800.

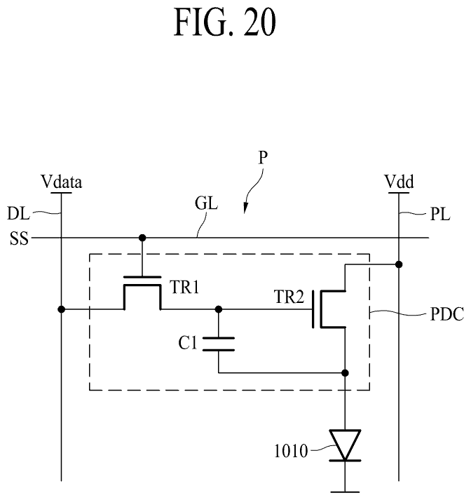

FIG. 20 is a circuit view illustrating any one pixel P of FIG. 19.

The circuit view of FIG. 20 is an equivalent circuit view for the pixel P of the display device 900 that includes an organic light emitting diode (OLED) as a display element 1010.

The pixel P includes a display element 1010 and a pixel driving circuit PDC for driving the display element 1010.

The display device 900 according to another exemplary embodiment of the present disclosure may include at least one of the above-described thin film transistors 100, 200, 300, 400, 500, 600, 700 and 800. In more detail, referring to FIG. 20, any one of the above-described thin film transistors 100, 200, 300, 400, 500, 600, 700 and 800 may be used as a first thin film transistor TR1 or a second thin film transistor TR2.

The first thin film transistor TR1 is connected to the gate line GL and the data line DL, and is turned on or off by the scan signal SS supplied through the gate line GL.

The data line DL provides a data voltage Vdata to the pixel driving circuit PDC, and the first thin film transistor TR1 controls applying of the data voltage Vdata. When the first thin film transistor TR1 is turned on, the data line DL provides the data voltage Vdata to the pixel driving circuit PDC.

A driving power line PL provides a driving voltage Vdd to the display element 1010, and the second thin film transistor TR2 controls applying of the driving voltage Vdd. The driving voltage Vdd is a pixel driving voltage for driving the organic light emitting diode (OLED) that is the display element 1010. When the second thin film transistor TR2 is turned on, the driving power line PL provides the driving voltage Vdd to the display element 1010.

When the first thin film transistor TR1 is turned on by the scan signal SS applied from the gate driver 320 through the gate line GL, the data voltage Vdata supplied through the data line DL is supplied to a gate electrode G2 of the second thin film transistor TR2 connected to the display element 1010. The data voltage Vdata is charged in a first capacitor C1 formed between the gate electrode G2 and a source electrode S2 of the second thin film transistor TR2.

The amount of current supplied to the organic light emitting diode (OLED), which is the display element 1010, through the second thin film transistor TR2 is controlled in accordance with the data voltage Vdata, whereby a gray scale of light output from the display element 1010 may be controlled.

According to the present disclosure, the following advantageous effects may be obtained.

According to one exemplary embodiment of the present disclosure, the non-conductorized region may be selectively formed in at least a portion of the active layer by using the barrier layer. As a result, a permeation depth of the conductorized region permeated into the channel portion may be controlled.

According to one exemplary embodiment of the present disclosure, the effective channel length may be stably obtained by controlling the barrier layer to adjust the permeation region and depth of the conductorized region.

The thin film transistor according to one exemplary embodiment of the present disclosure, which includes the barrier layer, has a sufficient effective channel length even though the length of the active layer is short, thereby having excellent driving stability.

The display device according to one exemplary embodiment of the present disclosure includes the thin film transistor having excellent stability as described above. Therefore, the display device according to one exemplary embodiment of the present disclosure may exhibit stable display performance.

It will be apparent to those skilled in the art that various modifications and variations can be made in the thin film transistor having a barrier layer and the display device comprising the same of the present disclosure without departing from the technical idea or scope of the disclosure. Thus, it is intended that the present disclosure cover the modifications and variations of this disclosure provided they come within the scope of the appended claims and their equivalents.

What is claimed is:

1. A thin film transistor, comprising:
an active layer;
a gate insulating layer on the active layer;
a gate electrode on the gate insulating layer; and
a first barrier layer on the gate insulating layer,
wherein the gate electrode and the first barrier layer are arranged to be spaced apart from each other,
a portion of the active layer overlaps the gate electrode to form a channel portion in the active layer,
the first barrier layer overlaps another portion of the active layer.

2. The thin film transistor of claim 1, wherein
the first barrier layer forms a first non-doping portion in the active layer,
the active layer includes the channel portion overlapping the gate electrode and having a first side and a second side; and a first connection portion that is in contact with the first side of the channel portion,
the first connection portion includes a first doping portion and the first non-doping portion, and
the first non-doping portion overlaps the first barrier layer but does not overlap the gate electrode.

3. The thin film transistor of claim 2, wherein the first non-doping portion has a carrier concentration higher than that of the channel portion.

4. The thin film transistor of claim 2, further comprising a source electrode that is in contact with the active layer,
wherein the source electrode is in contact with the first doping portion of the first connection portion.

5. The thin film transistor of claim 4, wherein the source electrode is in contact with the first barrier layer.

6. The thin film transistor of claim 1, wherein the first barrier layer includes the same material as that of the gate electrode, and is not electrically connected to the gate electrode, and/or
wherein the first barrier layer has the same thickness as that of the gate electrode.

7. The thin film transistor of claim 2, further comprising a second barrier layer on the gate insulating layer,
wherein the gate electrode and the second barrier layer are arranged to be spaced apart from each other,
the second barrier layer overlaps the active layer but does not overlap the first connection portion, and
the second barrier layer is arranged in a drain region.

8. The thin film transistor of claim 7, wherein the active layer further includes a second connection portion that is in contact with the second side of the channel portion,
the second connection portion includes a second doping portion and a second non-doping portion, and
the second non-doping portion overlaps the second barrier layer but does not overlap the gate electrode and the first barrier layer.

9. The thin film transistor of claim 8, wherein the second non-doping portion has a carrier concentration higher than that of the channel portion.

10. The thin film transistor of claim 8, further comprising a source electrode that is in contact with the active layer,
wherein the source electrode is in contact with the first doping portion of the first connection portion.

11. The thin film transistor of claim 10, wherein the source electrode is in contact with the first barrier layer and the second barrier layer.

12. The thin film transistor of claim 7, wherein each of the first barrier layer and the second barrier layer includes the same material as that of the gate electrode, and is not electrically connected to the gate electrode, and/or
wherein each of the first barrier layer and the second barrier layer has the same thickness as that of the gate electrode.

13. The thin film transistor of claim 7, wherein each of the first barrier layer and the second barrier layer has a spaced distance from the gate electrode in a range of 1.5 μm to 3.0 μm.

14. The thin film transistor of claim 7, wherein each of the first barrier layer and the second barrier layer has a first line segment and a second line segment,
a length of each of the first line segment and the second line segment of the first barrier layer ranges from 1.5 μm to 2.5 μm, and
a length of each of the first line segment and the second line segment of the second barrier layer ranges from 1.5 μm to 2.5 μm,
wherein the first line segment of the first barrier layer is a side facing the gate electrode among line segments defining a surface in which the first barrier layer and the gate insulating layer are in contact with each other, and the second line segment of the first barrier layer is a side intersecting the first line segment of the first barrier layer, and
the first line segment of the second barrier layer is a side facing the gate electrode among line segments defining a surface in which the second barrier layer and the gate insulating layer are in contact with each other, and the second line segment of the second barrier layer is a side intersecting the first line segment of the second barrier layer.

15. The thin film transistor of claim 7, wherein the first barrier layer is arranged in a source region, and the first barrier layer further includes at least one first sub-barrier layer,
the gate electrode and the first sub-barrier layer are arranged to be spaced apart from each other,
the first barrier layer and the first sub-barrier layer are arranged to be spaced apart from each other,
the first sub-barrier layer is arranged in the source region, and
a portion of the active layer overlaps the first sub-barrier layer.

16. The thin film transistor of claim 15, wherein the second barrier layer further includes at least one second sub-barrier layer,
the gate electrode and the second sub-barrier layer are arranged to be spaced apart from each other,
the second barrier layer and the second sub-barrier layer are arranged to be spaced apart from each other,
the second sub-barrier layer is arranged in a drain region, and
a portion of the active layer overlaps the second sub-barrier layer.

17. The thin film transistor of claim 16, wherein a spaced distance between the first barrier layer and the gate electrode is the same as a spaced distance between the first sub-barrier layer and the gate electrode, and
a spaced distance between the second barrier layer and the gate electrode is the same as a spaced distance between the second sub-barrier layer and the gate electrode.

18. The thin film transistor of claim 16, wherein a spaced distance between the first barrier layer and the gate electrode is different from a spaced distance between the first sub-barrier layer and the gate electrode, and
a spaced distance between the second barrier layer and the gate electrode is different from a spaced distance between the second sub-barrier layer and the gate electrode.

19. The thin film transistor of claim 16, wherein each of the first barrier layer, the second barrier layer, the first sub-barrier layer, and the second sub-barrier layer has a first line segment and a second line segment,
a length of at least one of the first line segment or the second line segment of the first barrier layer is different from a length of at least one of the first line segment or the second line segment of the first sub-barrier layer, and
a length of at least one of the first line segment or the second line segment of the second barrier layer is different from a length of at least one of the first line segment or the second line segment of the second sub-barrier layer,
wherein the first line segment of the first barrier layer is a side facing the gate electrode among line segments defining a surface in which the first barrier layer and the gate insulating layer are in contact with each other, and the second line segment of the first barrier layer is a side intersecting the first line segment of the first barrier layer,
the first line segment of the first sub-barrier layer is a side facing the gate electrode among line segments defining a surface in which the first sub-barrier layer and the gate insulating layer are in contact with each other, and the second line segment of the first sub-barrier layer is a side intersecting the first line segment of the first sub-barrier layer,
the first line segment of the second barrier layer is a side facing the gate electrode among line segments defining a surface in which the second barrier layer and the gate insulating layer are in contact with each other, and the second line segment of the second barrier layer is a side intersecting the first line segment of the second barrier layer, and
the first line segment of the second sub-barrier layer is a side facing the gate electrode among line segments defining a surface in which the second sub-barrier layer and the gate insulating layer are in contact with each other, and the second line segment of the second sub-barrier layer is a side intersecting the first line segment of the second sub-barrier layer.

20. A display device comprising thin film transistor of claim 1.
